(19) United States
(12) Patent Application Publication
(10) Pub. No.: US 2012/0070615 A1
(43) Pub. Date: Mar. 22, 2012

(54) POLYESTER FILM, METHOD FOR PRODUCING THE SAME, BACK SHEET FOR SOLAR CELLS, AND SOLAR CELL MODULE

(75) Inventors: Zemin SHI, Kanagawa (JP); Akihide FUJITA, Kanagawa (JP); Akira YAMADA, Kanagawa (JP)

(73) Assignee: FUJIFILM CORPORATION, Tokyo (JP)

(21) Appl. No.: 13/220,588

(22) Filed: Aug. 29, 2011

(30) Foreign Application Priority Data
Sep. 17, 2010 (JP) 2010-210185

(51) Int. Cl. B32B 3/00; C08G 63/183; B29C 55/02; H01L 31/0216; B29C 47/00

(52) U.S. Cl. 428/143; 264/210.5; 528/308.2

(57) ABSTRACT

Provided is a method for producing a polyester film, including: subjecting a polyester raw material resin, which contains a titanium compound and has an intrinsic viscosity of from 0.71 to 1.00, to melt extrusion using a twin-screw extruder which includes a cylinder; two screws disposed inside the cylinder; and a kneading disk unit disposed in at least a portion of a region extending from a 10%-position to a 65%-position of screw length with respect to an upstream end of the screws in a resin extrusion direction as a starting point, at a maximum shear rate generated inside the twin-screw extruder of from 10 sec⁻¹ to 2000 sec⁻¹;
forming an unstretched film by cooling and solidifying the melt extruded polyester resin on a cast roll; subjecting the unstretched film to biaxial stretching in a longitudinal direction and a lateral direction; and heat fixing the stretched film formed by biaxial stretching.

### CROSS-REFERENCE TO RELATED APPLICATION

This application claims priority under 35 USC 119 from Japanese Patent Application No. 2010-210185, filed on Sep. 17, 2010, the disclosure of which is incorporated by reference herein.

### BACKGROUND OF THE INVENTION

1. Field of the Invention

The present invention relates to a polyester film, a method for producing the polyester film, a back sheet for solar cells, and a solar cell module.

2. Description of the Related Art

In recent years, as there has been a rise in concerns about environmental problems such as global warming, more attention has been paid to photovoltaic power generation as a source of clean energy, and various forms of solar cells have been developed. Such a solar cell is generally constructed from plural solar cell modules in which plural pieces of photovoltaic cells wired in series or in parallel are packaged into a unit.

Solar cell modules are required to have high durability, weather resistance and the like, so that the solar cell modules are suited to outdoor use for long periods of time. A general solar cell module has a structure in which a transparent substrate formed of glass or the like, a filler layer formed of a thermoplastic resin such as an ethylene-vinyl acetate copolymer (EVA), plural pieces of a photovoltaic cell as a photovoltaic element, a filler layer which is identical with the aforementioned filler layer, and a back sheet are laminated in this order, and are integrated by a vacuum heat lamination method.

In a solar cell module, when water vapor, oxygen gas and the like infiltrate into the inside of the module, there is a risk that such infiltration may cause detachment and discoloration of the filler layers, corrosion of the wiring, functional deterioration of the photovoltaic cell, and the like. For this reason, a back sheet that is provided in the solar cell module is required to have gas barrier properties against water vapor, oxygen gas and the like, in addition to the basic performances such as strength, weather resistance and heat resistance.

Furthermore, recently there has been a trend toward setting the system voltage of a solar cell system as high as possible, in order to reduce the loss of power generation efficiency. Particularly, in recent years, there has been an increasing demand for solar cell systems having a system voltage of 1000 V or greater, and thus high resistance to a voltage ranging from about a conventional 600 V to 1000 V or higher is needed. Therefore, it is indispensable that a back sheet for solar cell modules be provided with high voltage resistance.

In recent years, polyester films have been used as back sheets for solar cell modules.

In this regard, from the viewpoints that strength and dimensional stability are demanded in the applications where a back sheet for solar cells is used, there is disclosed a polyethylene terephthalate-based resin film having a film thickness of from 70 μm to 400 μM as a relatively thick film for solar cells (see, for example, Japanese Patent Application Laid-Open (JP-A) No. 2009-149065).

On the other hand, a polyester film has a tendency to be susceptible to deterioration due to hydrolysis when the thickness increases. Therefore, a polyester film for solar cell applications is required to have long-term hydrolysis resistance.

As a technology related to the above description, it has been disclosed that hydrolysis resistance is improved by the selection of the composition of a polymerization catalyst that is used during the production of polyethylene terephthalate (PET) (see, for example, JP-A No. 2007-204538).

Furthermore, there is disclosed a method for producing a polyester sheet by performing melt extrusion under specific conditions using a vent-type twin-screw extruder, and it is believed that the decrease in the intrinsic viscosity (IV) of polyester caused by hydrolysis is suppressed to a minimal level (see, for example, Japanese Patent No. 3577178).

However, in the above-described conventional method intended to improve hydrolysis resistance by a polymerization catalyst, it is not necessarily possible to secure the hydrolysis resistance that is requested for solar cell applications, and it is difficult to maintain excellent weather resistance of a PET film over a long period of time.

Also, in the method for producing a polyester sheet by melt extrusion under specific conditions, the effect of improving long-term hydrolysis resistance is not sufficient, and a further improvement is required in terms of the hydrolysis resistance demanded in solar cell applications.

Meanwhile, it is preferable that the surface of a polyester film for solar cell applications is flat and smooth from the viewpoint of increasing voltage resistance; however, it is also required that a low friction coefficient is maintained after imparting smoothness.

The invention was made under such circumstances, and an object of the invention is to provide a polyester film capable of maintaining hydrolysis resistance and voltage resistance for a long time, a method for producing the polyester film, a back sheet for solar cells, and a solar cell module having long-term durability.

### SUMMARY OF THE INVENTION

The present invention has been made in view of the above circumstances and provides a polyester film, a method for producing the polyester film, a back sheet for solar cells, and a solar cell module.

A first aspect of the present invention provides a method for producing a polyester film, the method comprising: subjecting a polyester raw material resin, which contains a titanium compound as a polymerization catalyst and has an intrinsic viscosity of from 0.71 to 1.00, to melt extrusion using a twin-screw extruder which includes a cylinder; two screws disposed inside the cylinder; and a kneading disk unit disposed in at least a portion of a region extending from a 10%-position to a 65%-position of screw length with respect to an upstream end of the screws in a resin extrusion direction as a starting point, at a maximum shear rate (γ) generated inside the twin-screw extruder of from 10 sec⁻¹ to 2000 sec⁻¹; forming an unstretched film by cooling and solidifying the melt extruded polyester resin on a cast roll; subjecting the unstretched film to biaxial stretching in a longitudinal direction and a lateral direction; and heat fixing the stretched film formed by biaxial stretching.

A second aspect of the present invention provides a polyester film produced by the method for producing a polyester film as described in relation to the first aspect of the present invention.

A third aspect of the present invention provides a back sheet for solar cells including the polyester film as described in relation to the second aspect of the present invention.

A fourth aspect of the present invention provides a solar cell module having the polyester film as described in relation to the second aspect of the present invention.

### BRIEF DESCRIPTION OF THE DRAWINGS

FIG. 1 is a schematic diagram showing a configuration example of a twin-screw extruder used to carry out the method for producing a polyester film according to the invention.

FIG. 2 is a schematic cross-sectional view showing a configuration example of a solar cell module.

### DETAILED DESCRIPTION OF THE INVENTION

According to the invention, there can be provided a polyester film capable of maintaining hydrolysis resistance and voltage resistance for a long time, a method for producing the polyester film, and a back sheet for solar cells. Furthermore, according to the invention, a solar cell module having long-term durability can be provided.

Hereinafter, the method for producing a polyester film of the invention, a polyester film obtainable by the method, a back sheet for solar cells, and a solar cell module will be described in detail.

[Polyester Film and a Method for Producing the Same]

The method for producing a polyester film of the invention includes an extrusion step of subjecting a polyester raw material resin which contains a titanium compound as a polymerization catalyst and has an intrinsic viscosity of from 0.71 to 1.0, to melt extrusion using a twin-screw extruder which includes a cylinder; two screws disposed inside the cylinder; and a kneading disk unit disposed in at least a portion of the region inside the cylinder extending from the 10%-position to the 65%-position of the screw length with respect to the upstream end of the screws in the resin extrusion direction as a starting point, at a maximum shear rate (γ) that is generated inside the twin-screw extruder, of from 10 sec⁻¹ to 2000 sec⁻¹; an unstretched film formation step of forming an unstretched film by cooling and solidifying the melt extruded polyester resin on a cast roll; a biaxial stretching step of subjecting the unstretched film thus formed, to biaxial stretching in the longitudinal direction and the lateral direction; and a heat fixing step of heat fixing the stretched film thus formed by biaxial stretching.

Generally, when a polyester resin having a relatively high intrinsic viscosity (IV; =increase in molecular weight) of 0.71≦IV≦1.0, as a raw material resin, is melt extruded for an improvement of weather resistance, the polyester is likely to be decomposed due to the shear heat generation caused in the machine during the melt extrusion. Furthermore, although the shear rate achieved at the time of extruding the polyester from an extruder is usually set to a value close to the maximum shear rate that is exhibited by the extruder from the viewpoint of production cost and the like, when the intrinsic viscosity of the polyester raw material resin is increased for the purpose of further enhancing weather resistance for the solar cell applications or the like, there is a tendency for the shear heat generation in the machine to occur to a more significant extent. In this case, decomposition of the polyester is likely to be further promoted; however, according to the invention, since the conditions for twin-screw extrusion are appropriately set, that is, since a kneading disk unit is disposed at a predetermined position in the cylinder and the maximum shear rate (γ) occurring in the machine at the time of melt extrusion is set to 10 s⁻¹ to 2000 s⁻¹, shear heat generation can be suppressed while maintaining extrudability to a certain extent even when an increase in the IV is promoted. Therefore, hydrolysis resistance is excellent, and voltage resistance can be retained for a long time.

Thereby, the resulting polyester film has excellent hydrolysis resistance and exhibits high durability, for example, even in high temperature and high humidity environments such as outdoors, or in a use environment where the polyester film is left under exposure to sunlight for a long time.

—Extrusion Step—

In the extrusion step according to the invention, a polyester raw material resin which contains a titanium compound as a polymerization catalyst and has an intrinsic viscosity of from 0.71 to 1.0, is subjected to melt extrusion using a twin-screw extruder which includes a cylinder; two screws disposed inside the cylinder; and a kneading disk unit disposed in at least a portion of the region inside the cylinder extending from the 10%-position to the 65%-position of the screw length with respect to the upstream end of the screws in the resin extrusion direction as a starting point, at a maximum shear rate (y) that is generated inside the twin-screw extruder, of from 10 sec-1 to 2000 sec-1.

In the present step, a polyester resin which has been synthesized in advance using a titanium compound as a polymerization catalyst, is used as a raw material resin. The synthesis can be carried out by providing an esterification step in which a polyester is produced through an esterification reaction and a polycondensation reaction. This esterification step can be provided with (a) an esterification reaction, and (b) a polycondensation reaction for polycondensing the esterification reaction product produced by the esterification reaction. The details of the esterification reaction and the polycondensation reaction will be described below.

The intrinsic viscosity (IV) of the polyester raw material resin is in the range of from 0.71 to 1.00. When the value of IV is in the range described above, the mobility of molecules is decreased, and the generation of spherulites is suppressed, so that the water content is suppressed to a low level. Furthermore, there is also an effect of suppressing the destruction (peeling) at the interface with adhered objects (particularly, a sealing material (for example, EVA) provided on the cell-side substrate of a solar cell module), which results from the embrittlement occurring due to a decrease in the molecular weight. When the IV is less than 0.71, the generation of spherulites occurs to a great extent, so that hydrolysis resistance is deteriorated, the polymer becomes brittle, and voltage resistance is decreased. On the contrary, when the IV is greater than 1.00, the shear heat generation at the time of extrusion occurs to an excessively large extent, causing a decrease in hydrolysis resistance and voltage resistance. Furthermore, when the IV value is in the range described above, satisfactory stretchability is obtained, and unevenness in stretching is further suppressed.

Adjustment of the IV value to such values can be achieved by regulating the polymerization time during liquid state polymerization, and/or by solid state polymerization.

The IV value is more preferably 0.72 to 0.95, and even more preferably 0.73 to 0.90. As the polyester raw material resin according to the invention, a polyester resin obtained by solid state polymerization may be used. When solid state polymerization is employed, a polyester resin having the IV values described above can be suitably used as a raw material resin. The details of the solid state polymerization will be described below.

Here, the intrinsic viscosity (IV) is a value obtained by dividing the specific viscosity (ηₛₚ=ηᵣ−1), which is obtained by subtracting 1 from the ratio ηᵣ of solution viscosity (η) and solvent viscosity (η₀)(ηᵣ=η/η₀; relative viscosity), by the concentration, and extrapolating the resulting value to zero concentration. The IV is determined from the viscosity of a solution in a mixed solvent of 1,1,2,2-tetrachloroethane/phenol (=⅔ [mass ratio]) at 30° C.

According to the invention, melt extrusion is carried out using a twin-screw extruder which includes a cylinder; two screws disposed inside the cylinder; and a kneading disk unit disposed in at least a portion of the region extending from the 10%-position to the 65%-position of the screw length with respect to the upstream end of the screws in the resin extrusion direction as a starting point.

When the position of disposition of the kneading disk unit is further upstream of the 10%-position of the screw length, the resin is not sufficiently preheated, and accordingly, shear is applied while the resin is in the state of being insufficiently plasticized and not softened. As a result, shear heat generation occurs to a more significant extent. Furthermore, when the position of disposition of the kneading disk unit is further downstream of the 65%-position of the screw length, the distance of the cooling zone which lowers the resin temperature after shearing of the resin is shortened, and the effect of cooling the molten resin temperature is insufficient, so that the resin becomes susceptible to deterioration.

The position of disposition of the kneading disk unit is preferably in the region extending from the 15%-position to the 60%-position of the screw length, and more preferably in the region extending from the 20%-position to the 55%-position of the screw length, with respect to the upstream end of the screws in the resin extrusion direction as a starting point, from the viewpoints of preventing shear heat generation and decreasing the resin temperature (cooling effect).

The kneading disk unit is a part of a kneading screw, and usually uses plural disk elements. For example, when plural elliptical disk elements are disposed in a staggered manner, the flow between the disk elements can be divided in accordance with the angle of staggering the disk elements, and thereby, promotion of kneading can be attempted. One kneading disk unit refers to the region extending from the exposed surface of the element that serves as one end of the plural disk elements constituting the kneading disk unit, to the exposed surface of the element that serves as the other end (this distance is the length of one kneading disk unit).

Furthermore, the length of the kneading disk unit means, in the case where a kneading disk unit having plural kneading disk elements disposed therein is disposed at one site in a screw, the distance of the kneading disk unit in the screw longitudinal direction (distance spanning from the exposed surface of the element that serves as one end of the kneading disk unit, to the exposed surface of the element that serves as the other end). When such a kneading disk unit having plural kneading disk elements disposed therein is disposed at two or more sites, the length means the sum of the lengths of all kneading disk units.

In a twin-screw extruder, the kneading strength can be varied to a desired strength, by changing the length of the kneading disk units (disk number or disk thickness) disposed in the screw. According to the invention, the length of the kneading disk unit is preferably 1% to 30%, more preferably 2% to 25%, and particularly preferably 3% to 20%, of the screw length. As such, the invention is characterized in that the length of the kneading disk unit is adjusted to be shorter than the length generally employed. Conventionally, the length of the kneading disk unit is in many cases set to be 35% or greater of the screw length so as to achieve uniform kneading. When the kneading disk unit has a length in the range described above, it is preferable from the viewpoint that the volatiles and decomposition products (degradation products) originating from unstable sites of the polyester can be exhausted and removed, and the molten resin temperature can be lowered, and the hydrolysis resistance of the resulting polyester can be further increased. Specifically, when the length of the kneading disk unit is 30% or less of the screw length, the polyester molecules are not easily decomposed by the shear at the kneading disk unit, and the hydrolysis resistance of the polyester film formed therefrom is largely improved. Also, when the length of the kneading disk unit is 1% or greater of the screw length, volatile components derived from the low molecular weight components produced by the hydrolysis reaction can be effectively removed, and in the case of using additives such as fine particles, uniform dispersion can be achieved.

According to the invention, when the length of the kneading disk unit is set in the range described above, surprisingly, decomposition of polyester is suppressed. Furthermore, when additives are incorporated into the polyester, an effect of achieving a balance between the dispersion of the polyester and the additives can be obtained.

The type of the disk element that constitutes the kneading disk unit is classified into forward feed, backward feed and neutral. In the forward feed or backward feed, the kneading disks are installed in a twisted manner. The type in which the disk elements are disposed in a twisted manner in a direction reverse to the screw rotation direction (forward feed) has high transportability but has a weak dispersing effect. The type in which the disk elements are disposed in a twisted manner in a direction parallel to the screw rotation has a strong backflow (backward feed), and has high dispersion stress. The neutral type is a form in which the kneading disks are disposed in a straight manner, and is intermediate to the forward feed and the backward feed. Furthermore, the paddle width that constitutes each of the elements may be narrow, broad, or a combination thereof. The type, shape and paddle width of these kneading disk elements affect the behavior of the dispersing mixing shear of the resin inside the extruder. In order not to cause decomposition, low shear, less filling and less retention time are preferable. Therefore, it is effective to use a forward feed screw with a narrow paddle width. In addition to this, many types of special kneading disks are available, and those may also be used.

According to the invention, the screw may employ screw segments as a main component, and can be constituted by appropriately adding kneading disk segments so as to satisfy the ranges stipulated in the method for producing a polyester resin of the invention.

Furthermore, there are different types of shape for the kneading screw. For example, in a back screw in which grooves are cut unlike conventional forward feed screws, since the flow is reversed, the pressure at the upstream can be increased. When the pressure is increased, the upstream fills up, and accordingly strong shear stress is generated by the flowing resin. On the other hand, since the retention time is lengthened, deterioration of resin mixing is accelerated. For this reason, in order to suppress the polyester resin decomposition, a back screw is not suitable, and it is preferable to use a forward feed screw. However, when kneading performance such as in filler kneading is required, a back screw may also be used within the scope in which a balance between kneadability and control of the polyester resin can be achieved.

In regard to the shape of these kneading screws, those described in JP-A Nos. 2004-17414, 2002-86541, 5-104610, 5-237914, 6-55612, 6-126809, Japanese Unexamined Utility Model Registration Application Publication No. 6-68816, JP-A Nos. 8-258110, 9-136345, 11-10639, 2000-15629, 2001-162671, 2002-338728, 2003-39527, 2003-62892, 2004-284195, and 2007-182041 can be preferably used.

In the method for producing a polyester resin composition, a polyester resin and additives can be melt kneaded. At this time, if kneading is vigorous, decomposition of the polyester is further accelerated, and therefore, it is preferable to use a screw with low kneadability. From the viewpoint of performing such low kneading, it is preferable to adjust the length of the region by providing a high temperature retaining region in the region prior to kneading.

According to the invention, a twin-screw extruder which includes at least two screws having kneading disk units disposed therein, and a region which is present in the upstream of the kneading disk unit and extends over a length equivalent to 35% to 80% of the screw length is maintained in the temperature range of 260° C. to 300° C., is used, a composition containing a polyester raw material resin having a glass transition temperature of 180° C. or lower and additives is fed to this twin-screw extruder, and this composition is extruded through the entire screw length under the action of screw rotation. Thereby, plasticization of the polyester raw material resin can proceed as much as possible in the heating region upstream of the kneading disk unit where shear is imparted. Thus, it is effective for the removal of thermally volatile components, or for uniform dispersion of the polyester and the additives.

Furthermore, by heating the polyester raw material resin at high temperature in a heating region with a large breadth, the viscosity at the time of melting of the polyester raw material resin can be decreased, and the shear stress during shearing at the kneading disk units is weakened, so that thermal decomposition of the polyester or the occurrence of foreign substances can be suppressed. In addition, as a surprising effect, the occurrence of foreign substances and their frequency of occurrence at the polyester film surface thus obtained can be reduced.

Melt extrusion by a twin-screw extruder is carried out under the conditions in which the maximum shear rate (γ) occurring inside the twin-screw extruder at the time of extrusion is in the range of from 10 sec⁻¹ to 2000 sec-1. When the maximum shear rate (γ) is less than 10 sec⁻¹, the amount of molten components that flow back between the barrel and the flight increases, and the proportion of the resin with lengthened retention time increases, thereby causing the amount of decomposition products to increase. In addition to that, when the polyester raw material resin is kneaded, or additives are added, uniform dispersion of the additives is difficult, and protrusions with coarse surfaces due to aggregation frequently occur, and fall-off of fine particles due to stretching, or an increase in the protrusion height from the surface can be further increased. Furthermore, if the maximum shear rate (y) is greater than 2000 sec⁻¹, breakage of polyester molecules is brought about, the amount of terminal carboxyl groups (amount of terminal COOH) increases, and hydrolysis resistance is decreased.

When the maximum shear rate such as described above is provided, even in the case of using a polyester raw material resin with high IV, shear heat generation is suppressed, and thereby a polyester film having excellent hydrolysis resistance is obtained. Furthermore, in the case of adding additives such as fine particles and a UV absorber, the additives are uniformly dispersed in the polyester, the generation of coarse protrusions is suppressed (in combination with the stretching method that will be described below), and fine protrusions can be made to be present in a scattered manner on a film surface with excellent smoothness.

The maximum shear rate (γ) can be determined by the following formula (1).

γ=π·D·N/60h Formula (1)
γ: Maximum shear rate [s^{-1]}
D: Screw diameter [mm]
N: Speed of screw rotation [rpm]
h: Flight clearance [mm].

The maximum shear rate γ can be regulated by, for example, a method of controlling the speed of screw rotation, the screw shape, and the length of the kneading disk unit as desired when the extruder extrudes a resin.

According to the invention, from the viewpoints of more effectively suppressing the decomposition of the polyester and further increasing the long-term hydrolysis resistance, melt extrusion is preferably carried out at a maximum shear rate (γ), which occurs inside the twin-screw extruder at the time of extrusion, of 100 sec⁻¹ to 1500 sec⁻¹, and a more preferable maximum shear rate is in the range of 200 sec⁻¹ to 1200 sec⁻¹.

In order to achieve the maximum shear rate, it is preferable to set the speed of screw rotation of the twin-screw extruder to 30 rpm to 2000 rpm, more preferably to 50 rpm to 1500 rpm, and particularly preferably to 100 rpm to 1000 rpm.

Furthermore, although the kneading characteristics may vary depending on the difference in the rotation direction of the two screws, the engagement form of the two screws (for example, separated type, contact type, partially engaged type, and completely engaged type), and the like, the ratio of the screw length (L) to the screw diameter (D) (L/D) of the twin-screw extruder is preferably in the range of 10 to 100. At this time, in a suitable case, the direction of rotation is of the same direction, and the engagement form is of a partially engaged type or a completely engaged type.

Melt extrusion can be carried out by appropriately selecting a conventionally known twin-screw extruder equipped with twin screws for extruding a molten resin. Regarding the extruder, either a small-sized apparatus or a large-sized apparatus may be used. According to the invention, from the viewpoints of suppressing shear heat generation that is prone to occur in the case of production in large quantities, while further expecting an effect of increasing the hydrolysis resistance of the polyester film, a twin-screw extruder having a screw outer diameter of φ 150 mm or greater (more preferably, φ 200 mm to 400 mm) is preferable.

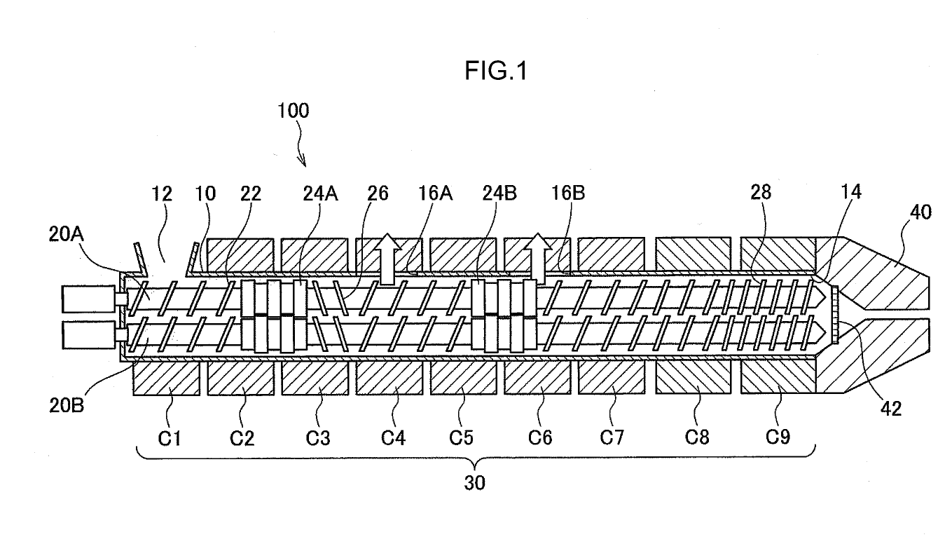

A configuration example of the twin-screw extruder is shown in FIG. 1. The twin-screw extruder 100 has, as shown in FIG. 1, a hopper 12, a cylinder (barrel) 10 having an extrusion port 14, and screws 20A and 20B, and the two screws are each provided with a first kneading disk unit 24A and a second kneading disk unit 24B. For the shape of the screws 20A and 20B, for example, a full-flight screw provided with a row of screw-shaped flights 22 arrayed at an equal pitch is used. Disposed around the barrel 10 is a temperature control unit 30 which controls the temperature inside the barrel, and a filter 42 and a die 40 are provided in front (in an extrusion direction) of the extrusion port 14. On the side of the extrusion port 14 of the screw, screws 28 with a shorter pitch are provided. Thereby, the resin transfer rate at the wall surface of the barrel 10 is increased, and the efficiency of temperature regulation can be increased. The temperature control unit 30 is composed of heating/cooling apparatuses C1 to C9, which are partitioned into 9 units along the longitudinal direction starting from a raw material feed port 12 toward the extrusion port 14, and the heating/cooling apparatuses C1 to C9 that are disposed in partition around the barrel 10 as such, compartmentalize the inside of the barrel 10 into various regions (zones) of, for example, heating melting units C1 to C7 and cooling units C8 to C9, and make it possible to control the temperature to a desired temperature for each of the regions. Furthermore, on the respective downstream sides of the kneading disk units 24A and 24B, vacuum vents 16A and 16B are provided. Furthermore, when a back screw 26 is used, a melt seal that is produced at the time of stopping the resin and drawing gas through the vents 16A and 16B, can be formed. The inside of the cylinder is provided with, as listed from the hopper side, a raw material supply unit, a screw compression unit, and a metering unit. The screw compression unit, which is not depicted, is a region in which the screw groove depth in the cylinder becomes smaller than the screw groove depth of the supply unit (for example, the screw groove depth gradually decreases from the screw groove depth of the supply unit), so that the volume (cylinder space volume) in which the resin can be transferred inside the cylinder with a decreasing screw groove depth, gradually decreases toward the resin extrusion direction. Therefore, the shear stress exerted on the resin over the range from the screw compression unit to the metering unit is increased. Therefore, heat generation is particularly prone to occur in this region.

The cylinder according to the invention preferably has an internal diameter (diameter) D of 140 mm or greater. According to the invention, it is particularly suitable to carry out melt extrusion by using a large-sized vent type twin-screw extruder having an inner diameter D of the cylinder of 150 mm or greater.

In regard to the ratio of the extrusion output Q [kg/hr] with respect to the inner diameter D of the cylinder, when the speed of screw rotation is designated as N [rpm], the ratio preferably satisfies the following formula.

5.2×10⁻⁶×D^{2.8}≦Q/N≦15.8×10⁻⁶×D^{2.8}

According to the invention, it is preferable to vent suction the interior of the twin-screw extruder.

In order to suppress the progress of the hydrolysis reaction when the polyester is exposed to high temperature, it is effective to exclude the moisture remaining in the resin and the moisture produced by the esterification reaction from the system other than cylinder as much as possible. Therefore, the twin-screw extruder is preferably equipped with a vent, and it is preferable to exclude moisture and the like while performing vacuum suction through the vent.

It is also preferable to exclude oxygen or volatile components such as oligomers, which remain in the polyester, by vacuum suction through the vent. In this case, the occurrence of oxidative decomposition of molten resin due to remaining oxygen or precipitation of the oligomers at the film surface can be suppressed.

Such vent suction is preferably carried out after purging the inside of the extruder with a gas stream of an inert gas (nitrogen or the like), while performing evacuation.

According to the invention, when a twin-screw extruder equipped with a gear pump for extrusion control which controls the extrusion output of the resin and a filter for foreign material removal which removes foreign materials in the resin in the downstream of the cylinder in the resin extrusion direction, is used, melt extrusion can be suitably achieved.

Specifically, from the viewpoint of enhancing the accuracy of the film thickness by reducing the fluctuation in the extrusion output, it is preferable to provide a gear pump that controls the extrusion output of the resin, between the extrusion outlet and the die. In this gear pump, a pair of gears consisting of a drive gear and a driven gear are provided in a mutually engaged manner, and when the drive gear is driven to induce engaged rotation of the two gears, the resin in a molten state is suctioned from the suction port formed in the housing into the cavity, and a constant amount of the resin is ejected through the ejection port formed on the same housing. Although the resin pressure at the front tip part of the extruder fluctuates slightly, the fluctuation is absorbed by using the gear pump, and the fluctuation of the resin pressure in the downstream of the film forming apparatus is minimized, so that the thickness fluctuation is improved. In order to enhance the performance of supplying a constant amount by the gear pump, a method of varying the speed of screw rotation and thereby regulating the pressure to be constant prior to gear pumping, can also be used.

Furthermore, from the viewpoint of removing any foreign material or additives (aggregates such as fine particles) in the polyester molten resin, it is preferable to provide a filter for foreign material removal. Filtration by a filter for foreign material removal is preferably carried out by, for example, filtration of a breaker plate type, or filtration using a filtration device incorporated with a leaf type disk filter. Filtration may be carried out in a single stage, or multi-stage filtration may be carried out. The filtration accuracy is preferably 40 μm to 3 μm, more preferably 20 μm to 3 μm, and even more preferably 10 μm to 3 μm. For the filter material, it is desirable to use stainless steel. For the constitution of the filter material, a woven wire material, or a product obtained by sintering a metal fiber or a metal powder (sintered filter material) can be used, and among them, a sintered filter material is preferable.

Here, the esterification step and the solid phase polymerization step for producing the polyester raw material resin of the invention will be described in detail.

The amount of terminal carboxylic acid groups (AV; hereinafter, may be referred to as a terminal COOH amount or AV) of the polyester raw material resin is preferably 8 eq/ton to 25 eq/ton. When the terminal COOH amount of the polyester resin used as a raw material resin is adjusted to the range described above, it is easier to suppress the terminal COOH amount of the polyester film obtainable after melt extrusion to a low level, and the hydrolysis resistance, that is, durability, of the final film can be drastically enhanced.

According to the invention, it is preferable to include the recovered waste of the polyester resin as the polyester raw material resin, in an amount of (greater than 0% by mass) to 15% by mass or less relative to the total mass. The recovered waste includes a pulverization product of polyester, a recycled material obtained by re-melting recovered polyester, and the like. When recycled waste is added, it is effective to achieve the filling ratio and the maximum shear stress σ of the resin such as described above, through the increase and decrease of the bulk specific gravity of raw material resins of different shapes. Specifically, for example, the volume of the polyester raw material resin can be regulated by a method of mixing two or more kinds of raw material resins having different sizes, or a method of mixing one kind of a polyester resin and two or more kinds of crushed materials of recovered film (for example, crushed waste of film crushed chips) as a raw material resin. Thereby, the filling ratio can be regulated.

In this case, the difference between the intrinsic viscosity of the recovered waste and the intrinsic viscosity of the raw material resin other than the recovered waste is preferably 0.01 to 0.2. When the difference is set in this range, an increase in the terminal COOH amount can be further suppressed by suppressed heat generation at the time of extrusion.

Among these, it is more preferable to incorporate a recovered waste of polyester in an amount in the range of (greater than 0% by mass and) 10% by mass or less relative to the total mass of the raw material resin, and to set a difference in the intrinsic viscosity between the recovered waste and the raw material resin other than the recovered waste, to the range of 0.01 to 0.1. Still more preferably, the recovered waste of polyester is incorporated in an amount in the range of (greater than 0% by mass) 8% by mass or less relative to the total mass of the raw material resin, and the difference in the intrinsic viscosity between the recovered waste and the raw material resin other than the recovered waste is set to the range of 0.01 to 0.05.

The bulk specific gravity of the raw material resin refers to the specific gravity that can be determined by introducing a powder into a container having a certain volume to be in a predetermined shape, and dividing the mass of the powder in the predetermined shape by the volume at that time (mass per unit volume). As the bulk specific gravity decreases, the raw material resin is bulkier.

According to the invention, the bulk specific gravity of the raw material resin is preferably in the range of 0.6 to 0.8. When this bulk specific gravity is 0.6 or greater, melt extrusion can be carried out more stably. When the bulk specific gravity is 0.8 or less, localized heat generation can be effectively suppressed.

—Esterification Step—

The esterification step can be provided with (a) an esterification reaction, and (b) a polycondensation reaction of subjecting the esterification reaction product produced by the esterification reaction, to a polycondensation reaction.

(a) Esterification Reaction

In the esterification reaction for polymerizing a polyester, an aromatic dicarboxylic acid and an aliphatic glycol are polycondensed, and a titanium compound is used as a polymerization catalyst used for the polycondensation reaction for this case.

Examples of the aromatic dicarboxylic acid include terephthalic acid, and 2,6-naphthalenedicarboxylic acid, and examples of the aliphatic glycol include ethylene glycol, diethylene glycol, and 1,4-cyclohexanedimethanol.

The amount of use of the titanium compound is preferably an amount which gives a titanium element content in the polyester resin of 20 ppm or less, and more preferably 10 ppm or less. The lower limit of the titanium element content in the polyester resin is usually 1 ppm, but is preferably 2 ppm.

When the amount of the titanium compound is in the range described above, a decomposition reaction does not easily occur during film production, and the molecular weight of the polyester is maintained without being lowered, so that the strength or heat resistance of the polyester is satisfactory. At the same time, handleability during the processing steps, and weather resistance and hydrolysis resistance when the polyester is used as a member for solar cells are excellent. Furthermore, when the amount of the titanium compound is 1 ppm or greater, productivity can be maintained, and the polyester resin has a desired degree of polymerization. Thus, it is suitable for the production of a polyester having a lowered amount of terminal carboxyl groups and excellent weather resistance and hydrolysis resistance.

In addition to the titanium compound, a phosphorus compound may be also used. In this case, the amount of the phosphorus compound is preferably an amount which gives an amount of phosphorus element in the polyester resin of 1 ppm or greater, and more preferably 5 ppm or greater. The upper limit of the amount of phosphorus element in the polyester resin is preferably 300 ppm, more preferably 200 ppm, and even more preferably 100 ppm.

When a phosphorus compound is used together with the titanium compound, weather resistance can be further enhanced. That is, the activity of titanium as a catalyst can be suppressed, and the polyester can be prevented from producing a decomposition reaction.

When the amount of the phosphorus compound is 300 ppm or less, gelling is prevented, and the phenomenon in which gel turns into a foreign material and appears in the film can be prevented. Thus, a polyester film having satisfactory quality is obtained. According to the invention, when the titanium compound and the phosphorus compound are incorporated in the ranges described above, weather resistance can be further enhanced.

Examples of the titanium compound include organic chelate titanium complexes, and generally, oxides, hydroxides, alkoxides, carboxylates, carbonates, oxalates and halides. According to the invention, an embodiment of using an organic chelate titanium complex is preferable, and to an extent of not impairing the effects of the invention, another titanium compound may be used in combination with the organic chelate titanium complex. Examples of the titanium compound include known compounds such as an alkyl titanate or a partial hydrolysate thereof, titanium acetate, and a titanyl oxalate compound. Specific examples include titanium alkoxides such as tetraethyl titanate, tetraisopropyl titanate, tetrabutyl titanate, tetra-n-propyl titanate, tetra-i-propyl titanate, tetra-n-butyl titanate, tetra-n-butyl titanate tetramer, tetra-t-butyl titanate, tetracyclohexyl titanate, tetraphenyl titanate, and tetrabenzyl titanate; titanium oxides obtainable by hydrolysis of titanium alkoxides; titanium-silicon or zirconium composite oxides obtainable by hydrolysis of mixtures of titanium alkoxides and silicon alkoxides or zirconium alkoxides; titanium acetate, titanium oxalate, potassium titanium oxalate, sodium titanium oxalate, potassium titanate, sodium titanate, titanic acid-aluminum hydroxide mixtures, titanium chloride, titanium chloride-aluminum chloride mixtures, and titanium acetylacetonate.

In the synthesis of a Ti-based polyester using such a titanium compound, for example, the methods described in Japanese Examined Patent Application (JP-B) No. 8-30119, Japanese Patent Nos. 2543624, 3335683, 3717380, 3897756, 3962226, 3979866, 3996871, 4000867, 4053837, 4127119, 4134710, 4159154, 4269704, and 4313538 can be applied.

Examples of the phosphorus compound include known compounds such as phosphoric acid, phosphorous acid or esters thereof, phosphonic acid compounds, phosphinic acid compounds, phosphonous acid compounds, and phosphinous acid compounds. Specific examples include orthophosphoric acid, dimethyl phosphate, trimethyl phosphate, diethyl phosphate, triethyl phosphate, dipropyl phosphate, tripropyl phosphate, dibutyl phosphate, tributyl phosphate, diamyl phosphate, triamyl phosphate, dihexyl phosphate, trihexyl phosphate, diphenyl phosphate, triphenyl phosphate; ethyl acid phosphate, dimethyl phosphite, trimethyl phosphite, diethyl phosphite, triethyl phosphite, dipropyl phosphite, tripropyl phosphite, dibutyl phosphite, tributyl phosphite, diphenyl phosphite, triphenyl phosphite, diamyl phosphite, triamyl phosphite, dihexyl phosphite, and trihexyl phosphite.

Furthermore, it is preferable not to incorporate any metal compound other than the titanium compound and the phosphorus compound. However, for an enhancement of the productivity of film, and for the purpose of lowering the volume-specific resistance value at the time of melting, a metal such as magnesium, calcium, lithium or manganese may be incorporated in an amount in the range of 100 ppm or less that is conventionally used, and the metal may be incorporated preferably in an amount in the range of 60 ppm or less, and even more preferably 50 ppm or less. In order to incorporate particles or various additives, in the case of using a method of using a master batch method or the like, antimony may be incorporated as a metal component other than the catalyst, and from the viewpoints of increasing hydrolysis resistance and weather resistance, the content of antimony relative to the total amount of the film can be adjusted to 30 ppm or less, in terms of the amount of antimony metal element, and preferably to 20 ppm or less.

A polyester film containing titanium and phosphorus in the amounts described above may be produced by mixing a polyester produced using a titanium compound as a catalyst and a polyester containing a phosphorus compound. In this case, a method in which a polyester containing a predetermined amount of a phosphorus compound is prepared as a master batch, and the polyester is mixed with a polyester produced using a titanium catalyst, is preferable. Examples of the method of preparing a master batch of a phosphorus compound include a method of performing polymerization using a germanium catalyst, a method of performing polymerization using a minimal amount of an antimony catalyst, and a method of adding the master batch by a process of melt extruding to a polyester produced using a titanium catalyst. Among them, it is particularly preferable to use a germanium catalyst.

The ratio of phosphorus element contained in the polyester film and titanium element derived from the catalyst, as a molar ratio (P/Ti), is preferably in the range of 1.0 to 20.0, and more preferably in the range of 5.0 to 15.0. When the ratio is in this range, weather resistance can be further enhanced.

According to the invention, preferable examples of the polyester include polyethylene terephthalate (PET), polybutylene terephthalate (PBT), polypropylene terephthalate, poly(1,4-cyclohexane dimethylene terephthalate), polyethylene naphthalate (PEN), polybutylene naphthalate, polypropylene naphthalate, and co-polycondensates thereof. Among these, polyethylene terephthalate and a co-polycondensate thereof are particularly preferable. The co-polycondensate preferably has a proportion of a constituent unit derived from ethylene terephthalate of 50% by mole or greater, and more preferably 70% by mole or greater.

(b) Polycondensation

Polycondensation produces polycondensates through subjecting the esterification reaction product produced by the esterification reaction, to a polycondensation reaction. The polycondensation reaction may be carried out in a single stage, or may be carried out in multiple stages.

The esterification reaction product such as an oligomer produced by the esterification reaction is subsequently supplied to a polycondensation reaction. This polycondensation reaction is suitably carried out by supplying the esterification reaction product to a multistage polycondensation reaction tank.

For example, the condensation polymerization reaction conditions, in the case of performing the reaction in a three-stage reaction tank, are that the reaction temperature at the first reaction tank is preferably 255° C. to 280° C., and more preferably 265° C. to 275° C., and the pressure is preferably 13.3×10⁻³ MPa to 1.3×10⁻³ MPa (100 Torr to 10 Torr), and more preferably 6.67×10⁻³ MPa to 2.67×10⁻³ MPa (50 Torr to 20 Torr). The reaction temperature at the second reaction tank is preferably 265° C. to 285° C., and more preferably 270° C. to 280° C., and the pressure is preferably 2.67×10⁻³ MPa to 1.33×10⁻⁴ MPa (20 Torr to 1 Ton), and more preferably 1.33×10⁻³ MPa to 4.0×10⁻⁴ MPa (10 Torr to 3 Torr). In the third and final reaction tank, the reaction temperature is preferably 270° C. to 290° C., and more preferably 275° C. to 285° C., and the pressure is preferably 1.33×10⁻³ MPa to 1.33×10⁻⁵ MPa (10 Torr to 0.1 Ton), and more preferably 6.67×10⁻⁴ MPa to 1.33×10⁻⁵ MPa (5 Torr to 0.1 Torr).

Solid State Polymerization Step—

According to the invention, a solid state polymerization step in which solid state polymerization of the polyester is carried out may be further provided in addition to the step described above. Solid state polymerization can be suitably carried out by using the polyester polymerized by the previously described esterification reaction or a commercially available polyester, which has been made into a fragmented form such as pellets. Specifically, for the solid state polymerization, the methods described in Japanese Patent Nos. 2621563, 3121876, 3136774, 3603585, 3616522, 3617340, 3680523, 3717392, and 4167159 can be used.

It is preferable that the solid state polymerization is carried out under the conditions of from 150° C. to 250° C., more preferably from 170° C. to 240° C., and even more preferably from 190° C. to 230° C., for from 5 hours to 100 hours, more preferably from 10 hours to 80 hours, and even more preferably from 15 hours to 60 hours. Furthermore, the solid state polymerization is preferably carried out in a vacuum or in a nitrogen (N₂) gas stream. Furthermore, a polyhydric alcohol (ethylene glycol or the like) may also be incorporated in an amount of from 1 ppm to 1%.

The solid state polymerization may be carried out in a batch mode (a mode in which the resin is placed in a vessel, and the resin is heated and stirred for a predetermined time in this vessel), or may be carried out, in a continuous mode (a mode in which the resin is placed in a heated tube, the resin is passed through this tube while the resin is heated for a predetermined residence time, and the resin is sequentially discharged out).

According to the invention, the degree of polymerization of the polyester used as a raw material resin may be appropriately selected in accordance with the characteristics required for the use applications of the polyester. However, in general, it is preferable to obtain a polyester having an IV value of from 0.3 to 0.65 by melt polycondensation, and increasing the IV value of the polyester obtained by melt polycondensation to an IV value of from 0.71 to 0.90 by solid state polycondensation.

According to the invention, it is preferable to incorporate inorganic particles or organic particles in order to improve the slip property, fixability and the like.

Examples of the inorganic particles include particles made of silicon dioxide, alumina, zirconium oxide, kaolin, talc, calcium carbonate, titanium oxide, barium oxide, carbon black, molybdenum sulfide, and antimony oxide. Among these, silicon dioxide is preferable from the viewpoint that the material is inexpensive and there are available particles of various particle sizes.

Examples of the organic particles include particles made of a polystyrene having a crosslinked structure established by a compound containing two or more carbon-carbon double bonds in a molecule (for example, divinylbenzene), or polyacrylate and polymethacrylate.

The inorganic particles and organic particles may be surface-treated. Examples of the surface treating agent include surfactants, polymers as dispersants, silane coupling agents and titanium coupling agents.

Furthermore, the polyester may also contain an antistatic agent, a defoamant, a coatability improving agent, a thickening agent, an antioxidant, an ultraviolet absorber, a foaming agent, a dye and a pigment. Furthermore, the polyester may also contain an organic solvent.

Unstretched Film Forming Step—

In the unstretched film forming step according to the invention, an unstretched film is formed by cooling and solidifying the polyester resin that has been melt extruded in the extrusion step on a cast roll (cooling roll).

The molten resin (melt) that is ejected in a band shape is cooled and solidified on a cast roll, and thus a polyester film having a desired thickness is obtained. At this time, the film thickness prior to stretching is preferably in the range of from 2600 μm to 6000 μm. When the film thickness is in this range, the polyester film may be subjected to subsequent stretching, and a polyester film having a thickness of from 260 μm to 500 μm can be obtained.

The thickness of the melt after solidification is preferably in the range of from 3100 μm to 6000 μm, more preferably in the range of from 3300 μm to 5000 μm, and even more preferably in the range of from 3500 μm to 4500 μm. When the thickness of the film after solidification and prior to stretching is 6000 μm or less, creases do not easily occur during the melt extrusion, and the occurrence of unevenness is suppressed. Furthermore, when the thickness after solidification is 2600 μm or greater, satisfactory withstand voltage characteristics may be obtained.

When the molten resin extruded from the extruder during the extrusion step is cast on a cast roll, it is preferable to set the average cooling rate of the molten resin in the temperature range of from 140° C. to 230° C., to the range of 230° C./min to 500° C./min. An enhancement of weather resistance requires a high stretching ratio, but for that reason, the average cooling rate is preferably in the range described above from the viewpoint of promoting the suppression of spherulite formation. The average cooling rate as used herein is a cooling rate on average at a temperature between 140° C. and 230° C., which exerts the greatest influence on the crystal formation, and as crystallization associated with spherulite formation is suppressed, weather resistance can be further increased.

When the average cooling rate is 230° C./min or higher, crystallization associated with spherulite formation is suppressed so that even when the film is stretched at a high stretch ratio, the film does not easily break, and a highly oriented stretched film is obtained. Furthermore, stretching irregularity is reduced to a large extent as spherulite formation is suppressed, and unevenness does not easily occur when the polyester resin is applied in the solar cell applications that will be described below. As such, hydrolysis resistance of the polyester film is increased to a large extent, and adhesion failure of the film can be suppressed by suppressed spherulite formation. In addition, when the average cooling rate is 500° C./min or less, rapid solidification of the melt is prevented and thus stretching unevenness and adhesion failure caused by breakage or crease formation on the cast roll can be prevented.

The average cooling rate is more preferably 280° C./min to 500° C./min, and more preferably 300° C./min to 450° C./min.

The average cooling rate can be regulated and realized by the methods shown below.

(1) The amount of cooling air and the temperature of cooling air are regulated.

(2) The molten resin (melt) is imparted with thickness unevenness of 0.1% to 5% (preferably, 0.2% to 3%, and more preferably 0.3% to 2%). Thereby, adhesion to the cooling roll is improved, and the cooling efficiency is enhanced, so that the melt can be produced at an average cooling rate in the range described above. The reason for this is believed to be as follows. The melt shrinks when brought into contact with the cooling roll, and when the melt is imparted with a condition of slight thickness unevenness as described above, the melt shrinks smoothly on the cooling roll and can be brought into uniform contact with the cooling roll, and thereby the cooling efficiency is improved. That is, if thickness unevenness is not imparted, sliding of the melt is likely to be decreased, and some parts adhere to the cooling roll, while the other parts are elongated between the points of adhesion (due to contraction stress). Thus, it is speculated that the melt is not brought into good contact with the cooling roll, and the cooling rate is decreased.

When the thickness unevenness is 5% or less, the cooling efficiency does not increase excessively, and spherulite formation is retained to a certain extent. Therefore, an effect of enhancing the film strength due to spherulites is obtained. Furthermore, when the thickness unevenness is 0.1% or greater, a decrease in the adhesive power due to cohesive destruction in the film can be prevented.

The amount of unmelted materials (foreign materials) in the molten resin (melt) is preferably 0.1 pieces/kg or less. Spherulites are easily formed from the unmelted materials in the melt acting as nuclei, but when the amount of the unmelted materials (foreign materials) is 0.1 pieces/kg or less, spherulite formation is suppressed, and the occurrence of stretching unevenness at the time of stretching can be further suppressed. Here, the unmelted materials (foreign materials) are crystals, or insoluble materials produced by decomposition, and these foreign materials refer to materials having a size of from 1 μm to 10 mm.

The amount of the unmelted materials is more preferably in the range of from 0.005 pieces/kg to 0.07 pieces/kg, and even more preferably in the range of from 0.1 pieces/kg to 0.05 pieces/kg, in the molten resin (melt). The unmelted materials (foreign materials) are determined by taking a magnified image of the polyester film using a phase contrast microscope and a CCD camera, and counting the number of foreign materials using an image processing apparatus.

Biaxial Stretching Step—

In the biaxial stretching step according to the invention, the unstretched film formed in the unstretched film forming step is biaxially stretched in the longitudinal direction and the lateral direction.

Specifically, it is preferable to guide an unstretched polyester film to a group of rolls heated to a temperature of from 70° C. to 140° C., to stretch the polyester film at a stretching ratio of from 3 times to 5 times in the longitudinal direction (vertical direction, that is, the direction of movement of the film), and to cool with a group of rolls at a temperature of from 20° C. to 50° C. Subsequently, while the two edges of the film are clamped with clips, the film is drawn to a tenter and stretched at a stretch ratio of from 3 times to 5 times in the direction perpendicular to the longitudinal direction (width direction) in an atmosphere heated to a temperature of from 80° C. to 150° C.

The stretch ratio is preferably set to from 3 times to 5 times in the longitudinal direction and the width direction, respectively. Furthermore, the area scale factor (longitudinal stretch ratio×lateral stretch ratio) is preferably from 9 times to 15 times. When the area scale factor is 9 times or greater, the reflection ratio, concealability and film strength of the biaxially stretched laminate film thus obtained are satisfactory, and when the area scale factor is 15 times or less, destruction during stretching can be avoided.

The method of performing biaxial stretching may be any of a sequential biaxial stretching method of performing stretching in the longitudinal direction and the width direction separately, as described above, and a simultaneous biaxial stretching method of performing stretching in the longitudinal direction and the width direction at the same time.

In order to complete the crystal orientation of the biaxially stretched film thus obtained and to impart planarity and dimensional stability, the biaxially stretched film is preferably subjected, still in the tenter, to a heat treatment for from 1 second to 30 seconds at a temperature ranging from the glass transition temperature (Tg) to a temperature below the melting point (Tm) of the raw material resin, and then is uniformly and slowly cooled and then cooled to room temperature. Generally, if the heat treatment temperature (Ts) is low, thermal shrinkage of the film is extensive. Therefore, in order to impart high thermal dimensional stability, the heat treatment temperature is preferably high. However, if the heat treatment temperature is excessively high, the oriented crystallinity is decreased, and as a result, the film thus formed may be deteriorated in hydrolysis resistance. Therefore, the heat treatment temperature (Ts) of the polyester film in the invention is preferably such that 40° C.≦(Tm−Ts)≦90° C. More preferably, the heat treatment temperature (Ts) is such that 50° C.≦(Tm−Ts)≦80° C., and even more preferably 55° C.≦(Tm−Ts)≦75° C.

The polyester film of the invention can be used as a back sheet that constitutes a solar cell module, but during the use of a module, the atmospheric temperature may increase to about 100° C. For that reason, the heat treatment temperature (Ts) is preferably from 160° C. to Tm-40° C. (provided that Tm-40° C.>160° C.). More preferably, the heat treatment temperature is from 170° C. to Tm-50° C. (provided that Tm-50° C.>170° C.), and even more preferably, Ts is from 180° C. to Tm-55° C. (provided that Tm-55° C.>180° C.).

Furthermore, if necessary, the polyester film may be subjected to a relaxation treatment of 3% to 12% in the width direction or the longitudinal direction.

Heat Fixing Step—

In the heat fixing step according to the invention, the stretched film formed by biaxially stretching in the biaxial stretching step described above is thermally fixed.

Heat fixing can be suitably carried out at a temperature of from 180° C. to 240° C. When the temperature at the time of heat fixing is 180° C. or higher, it is preferable from the viewpoint that the absolute value of the thermal shrinkage ratio is small. On the contrary, when the temperature at the time of heat fixing is 240° C. or lower, it is preferable from the viewpoint that the film does not easily turn opaque, and the frequency of rupture is small.

In this case, the duration of heat fixing is preferably 2 seconds to 60 seconds, more preferably 3 seconds to 40 seconds, and even more preferably 4 seconds to 30 seconds.

In general, the heat fixing of the film obtained after stretching is carried out using a heat fixing apparatus which has plural lines of plenum ducts having elongated hot air supply ports arranged perpendicularly to the longitudinal direction. In such a heat fixing apparatus, circulation of hot air is carried out so as to improve the heating efficiency. Air inside the heat fixing apparatus is suctioned by a circulator fan installed in the heat fixing apparatus, and the suctioned air is temperature-regulated and is discharged again through the hot air supply ports of the plenum ducts. As such, hot air circulation consisting of supply of hot air→suction by circulator fan→temperature regulation of suctioned air→supply of hot air is carried out.

Heat fixing during film production can be suitably carried out by (1) regulating the temperature and air volume of the plenum ducts of the heat fixing apparatus, (2) adjusting the blocking conditions of the hot air supply ports in the plenum ducts of the heat fixing apparatus, and (3) blocking heating in the region between the stretching zone and the heat fixing apparatus.

In the above item (1), it is preferable that, in order to perform heating and cooling stepwise, the heat fixing apparatus is generally divided into several heat fixing zones with different temperatures, and the temperature and air volume of the hot air blown out from the respective plenum ducts are regulated such that the product of the temperature difference and the air speed difference between two neighboring heat fixing zones is 250° C.·m/s or less in all cases. For example, in the case where the heat fixing apparatus is divided into a first heat fixing zone to a third heat fixing zone, it is preferable to regulate the temperature and air volume such that the product of the temperature difference and the air speed difference between the first zone and the second zone, and the product of the temperature difference and the air speed difference between the second zone and the third zone are all 250° C.·m/s or less. When the temperature and air volume of the hot air are regulated, circulation of hot air is smoothly achieved. Accordingly, a film having satisfactory planarity can be obtained even through heat fixing at high temperature. When the products of the temperature differences and the air speed differences between neighboring heat fixing zones are 250° C.·m/s or less (for example, the temperature differences between neighboring heat fixing zones are set to 20° C., and at the same time, the air speed differences between neighboring heat fixing zones are set to 10 m/s), circulation of hot air in the heat fixing apparatus is smoothly achieved. In addition, when the products of the temperature differences and the air speed differences between neighboring heat fixing zones are 250° C.·m/s or less, the temperature difference of the air flowing from the heat fixing zones at the upstream to the heat fixing zones at the downstream as an accompanying stream resulting from the passage of the film is decreased. Accordingly, it is preferable from the viewpoint that the temperature in the width direction of the heat fixing zones at the downstream is stabilized. Furthermore, the product of the temperature difference and the air speed difference is preferably 200° C.·m/s or less, and more preferably 150° C.·m/s or less.

The details of the above items (2) and (3) can be found by referring to the description of paragraphs [0081] and [0082] of JP-A No. 2009-149065.

—Relaxation Step—

The method for producing a polyester film of the invention is preferably provided with a relaxation step in which the heat-fixed, stretched film is subjected to a relaxation treatment in the longitudinal direction and the width direction, in addition to the heat fixing as described above. When the heat-fixed, stretched film is further subjected to relaxation in the longitudinal direction and the width direction of the film, the thermal shrinkage ratio at the film end edge areas can be reduced.

For example, the relaxation treatment in the longitudinal direction of the film allows the film to have a bendable structure between the clips. Thus, when the clip spacing in the longitudinal direction is adjusted, the clip spacing in the direction of movement is shortened, and the film is relaxed along the longitudinal direction. The relaxation ratio is preferably from 1% to 8%, and more preferably from 1.5% to 7%.

The temperature at the time of thermal relaxation (thermal relaxation temperature) is preferably 170° C. to 240° C., and more preferably 180° C. to 230° C.

As a preferable method for relaxation, a relaxation treatment in the longitudinal direction of a stretched film obtained after heat fixing can be carried out by clamping the two edges in the width direction of the stretched film using the clips installed in a pair of flexurally movable clip chains to which plural chain links are linked in a cyclic form, causing the stretched film to have a bendable structure between the clips, running the clips along guide rails to cause displacement of the bending angle of the chain links, and thereby shortening the distance between clips in the clip run direction (adjusting the clip spacing in the longitudinal direction). Such a method can be found by referring to the description of paragraph [0085] of JP-A No. 2009-149065. Specifically, there is a joint unit which links between a clip that holds a film edge and a clip adjacent to the foregoing clip, with a chain link that is flexurally movable, and as the bearing connected to this joint unit runs along the guide rail, the bending angle of the chain link is displaced. Thereby, the spacing in the direction of movement of the clips is shortened, and accordingly, relaxation in the longitudinal direction can be achieved.

Traditionally, a polyester film which has been stretched longitudinally and laterally has been subjected to a high temperature (220° C. or higher) heat fixing treatment in order to improve the dimensional change of the film. However, in such a high temperature heat fixing treatment, crystallization of strained non-crystalline molecules that are oriented proceeds, so that film clouding and long-term hydrolysis resistance are deteriorated. Furthermore, the high temperature heat fixing treatment is likely to cause coloration of the film. Particularly, in the solar cell applications (for example, a back sheet which is a rear surface protective layer provided on the side opposite to the side through which sunlight enters), the polyester film is made by lamination, coating or the like, but problems are likely to occur, such as curling and adhesive peeling of laminates, because of the thermal dimensional change of the polyester film during the processing steps of lamination and coating.

According to the invention, when the polyester film obtained after biaxial stretching is subjected to a heat fixing treatment at a relatively low temperature of 190° C. to 220° C., and then to a relaxation treatment in the longitudinal direction and the width direction, the strained non-crystalline molecules that are oriented are not destroyed, and while maintaining the long-term hydrolysis resistance, the dimensional stability of the film can be more effectively improved. That is, it is preferable to perform the heat fixing treatment in the tenter and then to shrink the polyester film at a relaxation ratio of 1% to 10% in the width direction, and it is desirable to relax the polyester film at a relaxation ratio of more preferably 1% to 7%, and even more preferably 2% to 5%.

Furthermore, it is preferable to reduce the relaxation ratio in the longitudinal direction to 1% to 8%. The relaxation ratio is more preferably 2% to 8%, and even more preferably 2% to 7%.

The term “relaxation ratio” as used herein refers to the value obtained by dividing the length to be relaxed, by the dimension prior to stretching.

The relaxation treatment in the longitudinal direction of the stretched film is preferably carried out by clamping the two edges in the width direction of the stretched film using the clips installed in a pair of flexurally movable clip chains in which plural chain links are linked in a cyclic form, running the clips along guide rails to cause displacement of the bending angle of the chain links, and thereby shortening the distance between clips in the clip run direction.

The relaxation treatment in the longitudinal direction can be continuously carried out in the process for producing a polyester film (in-line process), and processing can be carried out without adding any additional processes as subsequent steps.

The polyester film of the invention is a film produced by the method for producing a polyester film of the invention as described above.

The polyester film of the invention is a film obtainable by using a titanium compound as a polymerization catalyst, and preferably contains titanium element in the film in an amount in the range of from 1 ppm to 20 ppm, and more preferably from 2 ppm to 10 ppm.

The details of the titanium compound are as described above in regard to the method for producing a polyester film as described above.

The polyester film has an intrinsic viscosity of from 0.71 to 1.00, preferably 0.72 to 0.95, and even more preferably 0.73 to 0.90. The details of the intrinsic viscosity are as described above.

The hydrolysis resistance of the polyester film can be evaluated based on the retention time of breaking elongation. This is determined by a decrease in the breaking elongation when hydrolysis is accelerated by forcibly heat treating the polyester film (thermotreatment). A specific measurement method will be described below.

In the polyester film of the invention, it is preferable to set the thickness after stretching to the range of from 125 μm to 500 μm, from the viewpoint of imparting high withstand voltage characteristics in a practical thickness range. In order to impart high voltage resistance of 1000 V or higher, which has been demanded in recent years as a withstand voltage characteristic of polyester films, the thickness after stretching is preferably set to the range of from 180 μm to 400 μm. Furthermore, a decrease in the hydrolysis resistance can be suppressed to a low level. When the thickness is 260 μm or greater, the withstand voltage can be retained. On the contrary, a thickness exceeding 500 μm is not practical.

Among these, the thickness of the polyester film after stretching is preferably in the range of from 150 μm to 380 μm, and more preferably in the range of from 180 μm to 350 μm.

The withstand voltage is a value determined by measuring the voltage value at the time of destruction (short circuit) according to JIS C2151.

The polyester film of the invention preferably has a retention time of breaking elongation of 65 hours to 150 hours [h]. When the retention time of breaking elongation is 65 hours or longer, the progress of hydrolysis is suppressed as described above, and peeling and adhesion failure can be prevented. Furthermore, when the retention time of breaking elongation is 150 hours or less, excessive development of the crystal structure in the film is suppressed because the water content in the film is reduced, and the elastic modulus and extension stress can be maintained to the extent that peeling does not occur.

Among them, the retention time of breaking elongation is preferably 80 hours to 150 hours, and more preferably 90 hours to 150 hours.

According to the invention, an embodiment of film thickening as described above is preferable, and film thickening leads to an increase in the water content and a decrease in the hydrolysis resistance. If the thickness is simply increased to 260 μm or greater, the dimensional stability and hydrolysis resistance are decreased, and the desired long-term durability is not obtained. When the retention time of breaking elongation is in the range described above, embrittlement of the polyester film resulting from hydrolysis is suppressed, and a decrease in adhesion due to the cohesive destruction in the film at the time of adhesion can be suppressed.

The retention time of breaking elongation is the half-life of breaking elongation [hr] which can maintain the retention ratio of breaking elongation after a moisture-heat treatment (thermotreatment) at 120° C. and 100% RH, in the range of 50% or greater with respect to the breaking elongation prior to the moisture-heat treatment. The retention ratio of breaking elongation is determined by the following formula.

Retention ratio of breaking elongation [%]=(breaking elongation after thermotreatment)/(breaking elongation prior to thermotreatment)×100

Specifically, after a heat treatment (thermotreatment) lasting 10 hours to 300 hours [hr] at 120° C. and 100% RH is carried out at an interval of 10 hours, the breaking elongation of each thermotreated sample is measured, the measurement values thus obtained are divided by the breaking elongation prior to thermotreatment, and thereby the retention ratio of breaking elongation for each thermotreatment time is determined. Then, the retention ratio of breaking elongation is plotted, on the vertical axis, against the thermotreatment time on the horizontal axis, these data are fitted thereto, and the treatment time [hr] required until the retention ratio of breaking elongation is 50% or greater, is determined.

The breaking elongation is a value that can be determined by placing a sample of the polyester film on a tensile tester, measuring the elongation until breakage in the machine direction (MD; longitudinal direction) and the transverse direction (TD; lateral direction), respectively, by stretching the sample in an environment at 25° C. and 60% RH at a rate of 20 mm/min, and repeating the measurement five times at each point of 10 equal divisions in the width direction at an interval of 20 cm to obtain 50 points in total, and calculating an average of the obtained values. In addition, when the difference (absolute value) between the maximum value and the minimum value of the retention time of breaking elongation obtained at 50 points as described above is divided by the average value of the breaking elongation of the 50 points and is indicated as a percentage, the distribution of the retention time at breaking elongation [%] can be obtained.

The polyester film of the invention is such that the dimensional change before and after a heat treatment at 150° C. for 30 minutes is preferably 0.1% to 1% or less, and more preferably 0.1% to 0.5%, in both the longitudinal direction and the width direction.

Furthermore, the amount of foreign materials having a height of 0.5 μm or greater protruding from the surface of the polyester film, is preferably 1 to 100 pieces/100 cm², and more preferably 2 to 50 pieces/100 cm².

The average roughness Ra of the film is preferably in the range of 20 nm to 200 nm, and more preferably 25 nm to 150 nm. The average roughness Ra was measured at 20 sites each in the width direction and the longitudinal direction of the film using a Stylus type roughness tester SE3500K (manufactured by Kosaka Laboratory, Ltd.) according to JIS B0601, and the average value of the measurements was calculated as the average roughness Ra.

When one or two or more of the dimensional change, protrusion height, and average roughness Ra described above are satisfied, the polyester film of the invention exhibits excellent hydrolysis resistance over a long time period, and can attain excellent dimensional stability, scratch resistance and voltage resistance.

The polyester film according to the invention can further contain additives such as a light stabilizer and an antioxidant.

The polyester film of the invention preferably contains a light stabilizer. When the polyester film contains a light stabilizer, ultraviolet deterioration can be prevented. Examples of the light stabilizer include a compound which absorbs light rays such as ultraviolet rays and converts the light rays to thermal energy, and a material which captures the radicals generated as a result of light absorption and decomposition of a film or the like, and suppresses a decomposition chain reaction.

The light stabilizer is preferably a compound that absorbs light rays such as ultraviolet rays and converts the rays to thermal energy. When the polyester film contains such a light stabilizer, even if ultraviolet rays are continuously radiated over a long period, the effect of enhancing the partial discharge voltage can be maintained at a high value for a long time, or change of color tone, deterioration of strength and the like in the resin due to ultraviolet radiation are prevented.

For example, the ultraviolet absorber is such that as long as other properties of the polyester are not impaired, an organic ultraviolet absorber, an inorganic ultraviolet absorber and a combination of these can be preferably used without any particular limitation. On the other hand, the ultraviolet absorber is preferably a compound that has excellent resistance to moisture and heat and can be uniformly dispersed in the resin.

Examples of the ultraviolet absorber include, as organic ultraviolet absorbers, salicylic acid-based, benzophenone-based, benzotriazole-based and cyanoacrylate-based ultraviolet absorbers, and hindered amine-based ultraviolet stabilizers. Specific examples include salicylic acid-based agents such as p-t-butylphenyl salicylate and p-octylphenyl salicylate; benzophenone-based agents such as 2,4-dihydroxybenzophenone, 2-hydroxy-4-methoxybenzophenone, 2-hydroxy-4-methoxy-5-sulfobenzophenone, 2,2′, 4,4′-tetrahydroxybenzophenone, and bis(2-methoxy-4-hydroxy-5-benzoylphenyl)methane; benzotriazole-based agents such as 2-(2′-hydroxy-5′-methylphenyl)benzotriazole, 2-(2′-hydroxy-5′-methylphenyl)benzotriazole, and 2,2′-methylenebis[4-(1,1,3,3-tetramethylbutyl)-6-(2H-benzotraizol-2-yl)phenol]; cyanoacrylate-based agents such as ethyl-2-cyano-3,3′-diphenyl acrylate); triazine-based agents such as 2-(4,6-diphenyl-1,3,5-triazin-2-yl)-5-[(hexyl)oxy]-phenol; hindered amine-based agents such as bis(2,2,6,6-tetramethyl-4-piperidyl)sebacate, dimethyl succinate, 1-(2-hydroxyethyl)-4-hydroxy-2,2,6,6-tetramethylpiperidine polycondensate; and nickel bis(octylphenyl)sulfide, and 2,4-di-t-butylphenyl-3′,5′-di-t-butyl-4′-hydroxybenzoate.

Among these ultraviolet absorbers, from the viewpoints of having high resistance to repeated ultraviolet absorption, triazine-based ultraviolet absorbers are more preferable. These ultraviolet absorbers may be added into the film in the form of an ultraviolet absorber alone, or may be introduced in the form of a monomer having an ultraviolet absorber capability copolymerized into an organic conductive material or a non-water-soluble resin.

The content of the light stabilizer in the polyester film is preferably from 0.1% by mass to 10% by mass, more preferably from 0.3% by mass to 7% by mass, and even more preferably from 0.7% by mass to 4% by mass, based on the total mass of the polyester film. Thereby, a decrease in the molecular weight of polyester due to photodegradation over a long time period can be suppressed, and as a result, a decrease in the adhesive power caused by cohesion failure in the film can be suppressed.

Furthermore, the polyester film of the invention can contain, other than the light stabilizers, for example, a lubricant (fine particles), an ultraviolet absorber, a colorant, a heat stabilizer, a nucleating agent (a crystallizing agent), and a flame retardant as additives.

<Back Sheet for Solar Cells>

The back sheet for solar cells of the invention is constructed by providing the polyester film of the invention as described above, and can be constructed by providing at least one layer of functional layers such as a easy adhesive layer having high adhesiveness, an ultraviolet absorbing layer, and a white layer having light reflectivity, to an object of adhesion. When the polyester film described above is included, the back sheet exhibits durability performance that is stabilized for long-term use.

In the back sheet for solar cells of the invention, for example, functional layers such as described below may be provided by coating on a polyester film after uniaxial stretching and/or after biaxial stretching. For the coating, known coating techniques such as a roll coating method, a knife edge coating method, a gravure coating method and a curtain coating method can be used.

Furthermore, a surface treatment (flame treatment, corona treatment, plasma treatment, ultraviolet treatment, or the like) may also be carried out before coating of these functional layers. Furthermore, pasting of the functional layers by using an adhesive is also preferable.

—Easy Adhesive Layer—

When the polyester film of the invention constitutes a solar cell module, the polyester film preferably has an easy adhesive layer on the side facing the sealing material of the cell-side substrate to which a solar cell element is sealed with a sealant. When an easy adhesive layer exhibiting adhesiveness to an object of adhesion (for example, the surface of the sealant on the cell-side substrate to which a solar cell element is sealed with a sealing material) including a sealant (particularly, an ethylene-vinyl acetate copolymer), high firm adhesion between the back sheet and the sealing material can be attained. Specifically, the easy adhesive layer preferably has an adhesive power of 10 N/cm or greater, and preferably 20 N/cm or greater, particularly with respect to EVA (ethylene-vinyl acetate copolymer) that is used as a sealing material.

Furthermore, the easy adhesive layer is necessary to be such that peeling of the back sheet during the use of a solar cell module does not occur, and for that reason, it is preferable for the easy adhesive layer to have high moisture-heat resistance properties.

(1) Binder

The easy adhesive layer according to the invention can contain at least one binder.

Examples of the binder that can be use include polyester, polyurethane, an acrylic resin, and polyolefin. Among them, from the viewpoint of durability, an acrylic resin and polyolefin are preferable. As an acrylic resin, a composite resin of acrylic and silicone is also preferable. Preferable examples of the binder include the following compounds.

Examples of the polyolefin include CHEMIPEARL S-120 and CHEMIPEARL S-75N (trade names, all manufactured by Mitsui Chemicals, Inc.). Examples of the acrylic resin include JURYMER ET-410 and JURYMER SEK-301 (trade names, all manufactured by Nihon Junyaku Co., Ltd.). Furthermore, examples of the composite resin of acrylic and silicone include CERANATE WSA1060 and CERANATE WSA1070 (trade names, all manufactured by DIC Corp.), and H7620, H7630 and H7650 (trade names, all manufactured by Asahi Kasei Chemicals Corp.).

The amount of the binder is preferably in the range of 0.05 g/m² to 5 g/m², and particularly preferably in the range of 0.08 g/m² to 3 g/m². When the amount of the binder is 0.05 g/m² or greater, more satisfactory adhesive power is obtained, and when the amount of the binder is 5 g/m² or less, a more satisfactory surface state is obtained.

(2) Fine Particles

The easy adhesive layer according to the invention can contain at least one kind of fine particles. The easy adhesive layer preferably contains the fine particles in an amount of 5% by mass or greater relative to the total mass of the layer.

Suitable examples of the fine particles include inorganic fine particles of silica, calcium carbonate, magnesium oxide, magnesium carbonate and tin oxide. Particularly among these, from the viewpoint that a decrease in the adhesiveness is small when exposed to a high temperature and high humidity atmosphere, fine particles of tin oxide and silica are preferable.

The particle size of the fine particles is preferably about 10 nm to 700 nm, and more preferably about 20 nm to 300 nm. When fine particles having a particle size in the range described above are used, satisfactory high adhesiveness can be obtained. There are no particular limitations on the shape of the fine particles, but fine particles having a spherical shape, an indefinite shape, a needle-like shape and the like can be used.

The amount of addition of the fine particles in the easy adhesive layer is preferably 5% to 400% by mass, and more preferably 50% to 300% by mass, based on the binder in the easy adhesive layer. When the amount of addition of the fine particles is 5% by mass or greater, the adhesiveness when the easy adhesive layer is exposed to a high temperature and high humidity atmosphere is excellent. When the amount of addition is 400% by mass or less, the surface state of the easy adhesive layer is more satisfactory.

(3) Crosslinking Agent

The easy adhesive layer according to the invention can contain at least one crosslinking agent.

Examples of the crosslinking agent include epoxy-based, isocyanate-based, melamine-based, carbodiimide-based, and oxazoline-based crosslinking agents. From the viewpoint of securing adhesiveness after a lapse of time in a high temperature and high humidity atmosphere, among these crosslinking agents, particularly oxazoline-based crosslinking agents are preferable.

Specific examples of the oxazoline-based crosslinking agents include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis(2-oxazoline), 2,2′-methylenebis(2-oxazoline), 2,2′-ethylenebis-(2-oxazoline), 2,2′-trimethylenebis(2-oxazoline), 2,2′-tetramethylenebis(2-oxazoline), 2,2′-hexamethylenebis(2-oxazoline), 2,2′-octamethylenebis(2-oxazoline), 2,2′-ethylenebis-(4,4′-dimethyl-2-oxazoline), 2,2′-p-phenylenebis-(2-oxazoline), 2,2′-m-phenylenebis-(2-oxazoline), 2,2′-m-phenylenebis-(4,4′-dimethyl-2-oxazoline), bis(2-oxazolinylcyclohexane) sulfide, and bis(2-oxazolinylnorbornane) sulfide. Furthermore, (co)polymers of these compounds can also be preferably used.

Furthermore, as a compound having an oxazoline group, EPOCROS K2010E, EPOCROS K2020E, EPOCROS K2030E, EPOCROS WS500; EPOCROS WS700 (trade names, all manufactured by Nippon Shokubai Co., Ltd.), and the like can also be used.

A preferable amount of addition of the crosslinking agent in the easy adhesive layer is preferably 5% to 50% by mass, and more preferably 20% to 40% by mass, based on the binder in the easy adhesive layer. When the amount of addition of the crosslinking agent is 5% by mass or greater, a satisfactory crosslinking effect is obtained, and a decrease in the strength of the reflective layer or adhesion failure does not easily occur. When the amount of addition of the crosslinking agent is 50% by mass or less, the pot life of the coating liquid can be maintained longer.

(4) Additives

The easy adhesive layer according to the invention may further contain, if necessary, a known matting agent such as polystyrene polymethyl methacrylate or silica; a known surfactant such as an anionic surfactant or a nonionic surfactant; and the like.

(5) Method for Forming Easy Adhesive Layer

Examples of the method for forming the easy adhesive layer of the invention include a method of pasting a polymer sheet having high adhesiveness to the polyester film, and a method based on coating. A method based on coating is preferable from the viewpoints of being convenient and capable of forming a highly uniform thin film. As the coating method, for example, a known method of using a gravure coater or a bar coater can be used. The solvent for the coating liquid that is used for coating may be water, or an organic solvent such as toluene or methyl ethyl ketone. One kind of solvent may be used alone, or a mixture of two or more kinds of solvent may also be used.

(6) Properties

The thickness of the easy adhesive layer according to the invention is not particularly limited, but usually, the thickness is preferably 0.05 μm to 8 μm, and more preferably in the range of 0.1 μm to 5 μm. When the thickness of the easy adhesive layer is 0.05 μm or greater, the high adhesiveness that is needed can be easily obtained, and when the thickness is 8 μm or less, the surface state can be more satisfactorily maintained.

Furthermore, the easy adhesive layer according to the invention is preferably transparent from the viewpoint that when a colored layer (particularly a reflective layer) is disposed between the easy adhesive layer and the polyester film, the easy adhesive layer does not impair the effect of the colored layer.

—Ultraviolet Absorption Layer—

The polyester film of the invention may be provided with an ultraviolet absorption layer containing the ultraviolet absorbers described above. The ultraviolet absorption layer can be disposed at any position on the polyester film.

The ultraviolet absorber is preferably used after being dissolved or dispersed together with an ionomer resin, a polyester resin, a urethane resin, an acrylic resin, a polyethylene resin, a polypropylene resin, a polyamide resin, a vinyl acetate resin, a cellulose ester resin and the like, and preferably has a transmittance of 20% or less with respect to light with a wavelength of 400 nm or less.

—Colored Layer—

The polyester film of the invention can be provided with a colored layer. The colored layer is a layer disposed to be in contact with the surface of the polyester film or with another layer interposed therebetween, and can be constructed using a pigment or a binder.

A first function of the colored layer is to increase the power generation efficiency of a solar cell module by reflecting a portion of light in the incident light, which is not used in the power generation at the photovoltaic cell and reaches the back sheet, and returning the portion of light to the photovoltaic cell. A second function is to enhance the decorative properties of the external appearance when the solar cell module is viewed from the front surface side. Generally, when a solar cell module is viewed from the front surface side, the back sheet is seen around the photovoltaic cell. Thus, the decorative properties can be increased by providing a colored layer to the back sheet.

(1) Pigment

The colored layer according to the invention can contain at least one pigment. The pigment is preferably included in an amount in the range of 2.5 g/m² to 8.5 g/m². More preferable pigment content is in the range of 4.5 g/m² to 7.5 g/m². When the pigment content is 2.5 g/m² or greater, necessary coloration can be easily obtained, and the light reflectivity or decorative properties can be further improved. When the pigment content is 8.5 g/m² or less, the surface state of the colored layer can be more satisfactorily maintained.

Examples of the pigment include inorganic pigments such as titanium oxide, barium sulfate, silicon oxide, aluminum oxide, magnesium oxide, calcium carbonate, kaolin, talc, ultramarine blue, Prussian blue, and carbon black; and organic pigments such as phthalocyanine blue and phthalocyanine green. Among these pigments, a white pigment is preferable from the viewpoint of constituting the colored layer as a reflective layer that reflects sunlight incident thereon. Preferable examples of the white pigment include titanium oxide, barium sulfate, silicon oxide, aluminum oxide, magnesium oxide, calcium carbonate, kaolin, and talc.

The average particle size of the pigment is preferably 0.03 μm to 0.8 μm, and more preferably about 0.15 m to 0.5 μm. When the average particle size is in the range described above, the light reflection efficiency may be lowered.

In the case of constructing the colored layer as a reflective layer that reflects sunlight that has entered, the preferable amount of addition of the pigment in the reflective layer varies with the type or average particle size of the pigment used and cannot be defined briefly. However, the amount of addition of the pigment is preferably 1.5 g/m² to 15 g/m², and more preferably about 3 g/m² to 10 g/m². When the amount of addition is 1.5 g/m² or greater, a necessary reflection ratio can be easily obtained, and when the amount of addition is 15 g/m² or less, the strength of the reflective layer can be maintained at a higher level.

(2) Binder

The colored layer according to the invention can contain at least one binder. When the colored layer contains a binder, the amount of the binder is preferably in the range of 15% to 200% by mass, and more preferably in the range of 17% to 100% by mass, based on the pigment. When the amount of the binder is 15% by mass or greater, the strength of the colored layer can be maintained more satisfactorily, and when the amount is 200% by mass or less, the reflection ratio or decorative properties are lowered.

Examples of the binder suitable for the colored layer include polyester, polyurethane, an acrylic resin, and polyolefin. The binder is preferably an acrylic resin or a polyolefin from the viewpoint of durability. As an acrylic resin, a composite resin of acrylic and silicone is also preferable. Preferable examples of the binder include the following compounds.

Examples of the polyolefin include CHEMIPEARL S-120 and CHEMIPEARL S-75N (trade names, all manufactured by Mitsui Chemicals, Inc.). Examples of the acrylic resin include JURYMER ET-410 and JURYMER SEK-301 (trade names, all manufactured by Nihon Junyaku Co., Ltd.). Furthermore, examples of the composite resin of acrylic and silicone include CERANATE WSA1060 and CERANATE WSA1070 (trade names, all manufactured by DIC Corp.), and H7620, H7630 and H7650 (trade names, all manufactured by Asahi Kasei Chemicals Corp.).

(3) Additives

The colored layer according to the invention may further contain, if necessary, a crosslinking agent, a surfactant, a filler and the like, in addition to the binder and the pigment.

Examples of the crosslinking agent include epoxy-based, isocyanate-based, melamine-based, carbodiimide-based, and oxazoline-based crosslinking agents. The amount of addition of the crosslinking agent in the colored layer is preferably 5% to 50% by mass, and more preferably 10% to 40% by mass, based on the binder in the colored layer. When the amount of addition of the crosslinking agent is 5% by mass or greater, a satisfactory crosslinking effect is obtained, and the strength or adhesiveness of the colored layer can be maintained at a high level. When the amount of addition of the crosslinking agent is 50% by mass or less, the pot life of the coating liquid can be maintained longer.

As the surfactant, a known surfactant such as an anionic surfactant or a nonionic surfactant can be used. The amount of addition of the surfactant is preferably 0.1 mg/m² to 15 mg/m², and more preferably 0.5 mg/m² to 5 mg/m². When the amount of addition of the surfactant is 0.1 mg/m² or greater, the occurrence of cissing can be effectively suppressed, and when the amount of addition is 15 mg/m² or less, excellent adhesiveness is obtained.

Furthermore, the colored layer may also contain a filler such as silica, apart from the pigment described above. The amount of addition of the filler is preferably 20% by mass or less, and more preferably 15% by mass or less, based on the binder in the colored layer. When the colored layer contains a filler, the strength of the colored layer can be increased. Furthermore, when the amount of addition of the filler is 20% by mass or less, the proportion of the pigment can be retained, and therefore, satisfactory light reflectivity (reflection ratio) or decorative properties are obtained.

(4) Method for Forming Colored Layer

Examples of the method for forming a colored layer include a method of bonding a polymer sheet containing a pigment on the polyester film, a method of co-extruding the colored layer during the molding of the polyester film, and a method based on coating. Among these, the method based on coating is preferable from the viewpoint of being convenient and capable of forming a highly uniform thin film. As the coating method, for example, a known method of using a gravure coater or a bar coater can be used. The solvent for the coating liquid used in the coating may be water, or may be an organic solvent such as toluene or methyl ethyl ketone. However, from the viewpoint of environmental burden, it is preferable to use water as the solvent.

One kind of solvent may be used alone, or mixtures of two or more kinds may also be used.

(5) Properties

It is preferable that the colored layer contains a white pigment and is constructed as a white layer (light reflective layer). In the case where the colored layer is a reflective layer, the light reflection ratio for light at 550 nm is preferably 75% or greater. When the reflection ratio is 75% or greater, the portion of sunlight that passes through the photovoltaic cell and is not used in power generation can be returned to the cell, and a large effect of increasing the power generation efficiency is obtained.

The thickness of the white layer (light reflective layer) is preferably 1 μl to 20 μm, more preferably 1 μm to 10 μm, and even more preferably about 1.5 μm to 10 μm. When the thickness is 1 μm or greater, necessary decorative properties or a reflection ratio can be easily obtained, and when the thickness is 20 μm or less, the surface state may be deteriorated.

—Undercoat Layer—

The polyester film of the invention can be provided with an undercoat layer. The undercoat layer may be such that, for example, when a colored layer is provided, the undercoat layer may be provided between the colored layer and the polyester film. The undercoat layer can be constructed by using a binder, a crosslinking agent, a surfactant and the like.

Examples of the binder that is included in the undercoat layer include polyester, polyurethane, an acrylic resin, polyolefin and the like. The undercoat layer may contains an epoxy-based, isocyanate-based, melamine-based, carbodiimide-based or oxazoline-based crosslinking agent; an anionic or nonionic surfactant; a filler such as silica; and the like, in addition to the binder.

There are no particular limitations on the method for coating and forming the undercoat layer, or the solvent for the coating liquid used in the method.

As the coating method, for example, a gravure coater or a bar coater can be used. The solvent may be water, or may be an organic solvent such as toluene or methyl ethyl ketone. One kind of solvent may be used alone, or mixtures of two or more kinds of solvent may also be used.

Coating may be carried out such that the undercoat layer may be applied on a polyester film obtained after biaxial stretching, or may be applied on a polyester film obtained after uniaxial stretching. In this case, the polyester film may be further stretched, after applying the undercoat layer, in the direction different from the direction of initial stretching. Furthermore, the undercoat layer may be applied on a polyester film prior to stretching, and then the polyester film may be stretched in two directions.

The thickness of the undercoat layer is preferably 0.05 μm to 2 μm, and more preferably in the range of about 0.1 μm to 1.5 μm. When the layer thickness is 0.05 μm or greater, necessary adhesiveness can be easily obtained, and when the thickness is 2 μm or less, the surface state can be satisfactorily maintained.

—Fluorine-Based Resin Layer and Silicon-Based Resin Layer—

The polyester film of the invention is preferably provided with at least one of a fluorine-based resin layer and a silicon-based (Si-based) resin layer. When a fluorine-based resin layer or a Si-based resin layer is provided, prevention of contamination of the polyester surface and an enhancement of weather resistance can be promoted. Specifically, it is preferable that the polyester film has a fluorine resin-based coating layer such as those described in JP-A Nos. 2007-35694 and 2008-28294 and WO 2007/063698.

Furthermore, it is also preferable to adhere a fluorine-based resin film such as TEDLAR (trade name, manufactured by DuPont Company) to the polyester film.

The thicknesses of the fluorine-based resin layer and the Si-based resin layer are respectively preferably in the range of from 1 μm to 50 μm, more preferably in the range of from 1 μm to 40 μm, and even more preferably 1 μm to 10 μm.

—Inorganic Layer—

The polyester film of the invention which is further provided with an inorganic layer is also a preferable embodiment. When an inorganic layer is provided, functions such as moisture-proof property that prevents penetration of water or gas into the polyester or gas barrier properties can be imparted. The inorganic layer may be provided on the front surface or back surface of the polyester film, but from the viewpoints of waterproof and moisture-proof, the inorganic layer is suitably provided on the opposite side of the side which faces the cell-side substrate (the surface side where the colored layer or the easy adhesive layer is formed) of the polyester film.

The steam permeation amount (moisture permeability) of the inorganic layer is preferably 10⁰ g/m²·d to 10⁻⁶ g/m²·d, more preferably 10¹ g/m²·d to 10⁻⁵ g/m²·d, and even more preferably 10² g/m²·d to 10⁻⁴ g/m²·d.

In order to form an inorganic layer having such moisture permeability, a dry method such as described below is suitable.

Examples of the method for forming an inorganic layer having gas barrier properties (hereinafter, also referred to as a gas barrier layer) by a dry method include vacuum deposition methods such as resistance heating deposition, electron beam deposition, induction heating deposition, and assisted methods using a plasma or an ion beam; sputtering methods such as a reactive sputtering method, an ion beam sputtering method, and an ECR (electron cyclone resonance) sputtering method; physical vapor deposition methods (PVD methods) such as an ion plating method; and chemical vapor deposition methods (CVD methods) using heat, light or plasma. Among them, vacuum deposition methods in which a film is formed by a deposition method in a vacuum, are preferable.

Here, when the material that forms the gas barrier layer contains an inorganic oxide, an inorganic nitride, an inorganic oxynitride, an inorganic halide, an inorganic sulfide or the like as main constituent components, a material having the same composition as the gas barrier layer that is to be formed can be directly volatilized and deposited on a substrate. However, in the case of performing this method, the composition changes during volatilization, and as a result, the film thus formed may not exhibit uniform characteristics. For that reason, the following methods may be used: (1) a method of using, as a volatile source, a material having the same composition as that of the barrier layer to be formed, and volatilizing the material while introducing an auxiliary gas into the system, such as oxygen gas in the case of an inorganic oxide; nitrogen gas in the case of an inorganic nitride; a mixed gas of oxygen gas and nitrogen gas in the case of an inorganic oxynitride; a halogen-based gas in the case of an inorganic halide; and a sulfur-based gas in the case of an inorganic sulfide; (2) a method of using a group of inorganic materials as a volatile source, introducing oxygen gas in the case of an inorganic oxide; nitrogen gas in the case of an inorganic nitride; a mixed gas of oxygen gas and nitrogen gas in the case of an inorganic oxynitride; a halogen-based gas in the case of an inorganic halide; and a sulfur-based gas in the case of an inorganic sulfide, into the system while volatilizing the inorganic material group, and performing deposition on the substrate surface while allowing the inorganic materials and the introduced gas to react with each other; and (3) a method of using an inorganic material group as a volatile source, forming a layer of the inorganic material group by volatilizing the inorganic material group, subsequently maintaining the layer in an oxygen gas atmosphere in the case of an inorganic oxide; in a nitrogen gas atmosphere in the case of an inorganic nitride; in a mixed gas atmosphere of oxygen gas and nitrogen gas in the case of an inorganic oxynitride; in a halogen-based gas atmosphere in the case of an inorganic halide; and in a sulfur-based gas atmosphere in the case of an inorganic sulfide, and thereby allowing the inorganic material layer and the introduced gas to react with each other.

Among these, from the viewpoint that it is easier to volatilize from the volatile source, the method (2) or (3) is preferably used. Furthermore, from the viewpoint that control of the film quality is easier, the method (2) is more preferably used. When the barrier layer is an inorganic oxide, a method of using an inorganic material group as a volatile source, volatilizing this material group to form a layer of the inorganic material group, and then leaving the layer to stand in air to naturally oxidize the inorganic material group, is also preferable from the viewpoint that the layer formation is facilitated.

Furthermore, it is also preferable to paste an aluminum foil and to use it as a barrier layer. The thickness is preferably from 1 μm to 30 μm. When the thickness is 1 μm or greater, it is difficult for water to penetrate into the polyester film during a lapse of time (thermo), and hydrolysis does not easily occur. When the thickness is 30 μm or less, the thickness of the barrier layer does not increase excessively, and deposits do not occur on the film due to the stress of the barrier layer.

<Solar Cell Module>

The solar cell module of the invention is constructed by disposing a solar cell element that converts light energy of sunlight into electric energy, between a transparent substrate through which sunlight enters and the polyester film (back sheet for solar cells) of the invention described above. The solar cell module can be constructed by sealing the gap between the substrate and the polyester film using, for example, a resin (so-called sealing material) such as an ethylene-vinyl acetate copolymer.

The details of the solar cell module, the photovoltaic cell, and members other than the back sheet are described in, for example, “Constituent Materials for Photovoltaic Power Generation System” (edited by Eiichi Sugimoto, Kogyo Chosakai Publishing Co., Ltd. published in 2008).

The transparent substrate may desirably have light transmitting properties by which sunlight can be transmitted, and can be appropriately selected from base materials that transmit light. From the viewpoint of power generation efficiency, a base material having higher light transmittance is preferable, and as such a substrate, for example, a glass substrate, a substrate of a transparent resin such as an acrylic resin, and the like can be suitably used.

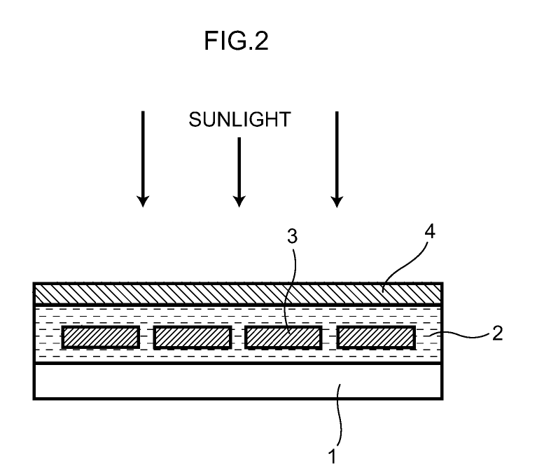

The solar cell power generating module may be constituted such that, for example, as shown in FIG. 2, a power generating element (solar cell element) 3 connected to a lead wiring that extracts electricity (not depicted) is sealed with a sealing agent 2 such as an ethylene-vinyl acetate copolymer-based (EVA-based) resin, and this is placed between a transparent substrate 4 made of glass or the like and a back sheet 1 formed using the polyester film of the invention, to be adhered to each other.

As the solar cell element, various known solar cell elements such as silicon-based devices such as single crystal silicon, polycrystalline silicon and amorphous silicon; and Group III-V or Group II-VI compound semiconductor-based elements such as copper-indium-gallium-selenium, copper-indium-selenium, cadmium-tellurium and gallium-arsenic, can be applied.

### EXAMPLES

Hereinafter, the invention will be more specifically described by way of Examples, but the invention is not intended to be limited to the following Examples as long as the main gist is maintained. In addition, the unit “parts” in the Examples is on a mass basis.

### Examples 1 to 29 and Comparative Examples 1 to 8

### 1. Production of Polyester Pellets

(1) Ti Catalyst PET

In a first esterification reaction tank, 4.7 tons of high purity terephthalic acid and 1.8 tons of ethylene glycol were mixed over 90 minutes to form a slurry, and the slurry was continuously supplied to the first esterification reaction tank at a flow rate of 3800 kg/h. Furthermore, an ethylene glycol solution of a citric acid chelated titanium complex (VERTEC AC-420, trade name, manufactured by Johnson Matthey Plc.) having Ti metal coordinated with citric acid was continuously supplied, and a reaction was carried out at a temperature inside the reaction tank of 250° C. and for an average retention time of about 4.3 hours with stirring. At this time, the citric acid chelated titanium complex was continuously added such that the addition amount of Ti element was 9 ppm. At this time, the acid value of the oligomer thus obtained was 600 eq/ton.

This reaction product was transferred to a second esterification reaction tank, and with stirring, the reaction product was allowed to react at a temperature inside the reaction tank of 250° C. for an average retention time of 1.2 hours. Thus, an oligomer having an acid value of 200 eq/ton was obtained. The inside of the second esterification reaction tank was divided into three zones, so that the above reaction was conducted at the first zone, and an ethylene glycol solution of magnesium acetate was continuously supplied at the second zone such that the addition amount of Mg element was 75 ppm, and subsequently an ethylene glycol solution of trimethyl phosphate was continuously supplied at the third zone such that the addition amount of P element was 65 ppm. Thus, the esterification reaction product obtained.

The esterification reaction product obtained as described above was continuously supplied to a first condensation polymerization reaction tank, and with stirring, condensation polymerization was carried out at a reaction temperature of 270° C. and a pressure inside the reaction tank of 2.67×10⁻³ MPa (20 Torr) for an average retention time of about 1.8 hours. Furthermore, the reaction product was transferred to a second condensation polymerization reaction tank, and in this reaction tank, a reaction (condensation polymerization) was carried out with stirring under the conditions of a temperature inside the reaction tank of 276° C. and a pressure inside the reaction tank of 6.67×10⁻⁴ MPa (5.0 Torr) for a retention time of about 1.2 hours.

Subsequently, the reaction product was further transferred to a third condensation polymerization reaction tank, and in this reaction tank, a reaction (condensation polymerization) was carried out under the conditions of a temperature inside the reaction tank of 278° C. and a pressure inside the reaction tank of 2.0×10⁻⁴ MPa (1.5 Torr) for a retention time of 1.5 hours. Thus, a reaction product (polyethylene terephthalate (PET)) was obtained.

Subsequently, the reaction product thus obtained was ejected in cold water into a strand form, and the strands were immediately cut to produce pellets of a polyester resin <cross-section: major axis about 2 mm to 5 mm, minor axis about 2 mm to 3 mm, length: about 47 mm>.

The polyester resin thus obtained was analyzed using high resolution type high frequency inductively coupled plasma-mass analysis (trade name: HR—ICP-MS; ATTOM manufactured by SII Nanotechnology, Inc.), and it was found that Ti=9 ppm, Mg=75 ppm, and P=60 ppm. Furthermore, the PET thus obtained had an intrinsic viscosity (IV) of 0.65, a concentration of terminal carboxyl groups (AV) of 22 eq/ton, a melting point of 257° C., and a solution haze of 0.3%. The analysis of IV and AV was carried out by the method described below.

(2) Sb Catalyst PET

100 parts of dimethyl terephthalate and 70 parts of ethylene glycol were subjected to a transesterification reaction according to a conventional method, using calcium acetate monohydrate and magnesium acetate tetrahydrate as transesterification catalysts. Subsequently, trimethyl phosphate was added, and the transesterification reaction was substantially terminated. Furthermore, titanium tetrabutoxide and antimony trioxide were added thereto. Thereafter, polycondensation was carried out at high temperature and in a high vacuum according to a conventional method, and thus a polyethylene terephthalate (PET) having an intrinsic viscosity (IV)=0.60 and a concentration of terminal carboxyl groups (AV) of 27 eq/ton was obtained. The analysis of IV and AV was carried out by the method described below.

The PET thus obtained was ejected into cold water in a strand shape, and was immediately cut. Thus, PET pellets (cross-section: major axis about 2 mm to 5 mm, minor axis about 2 mm to 3 mm, length: about 47 mm) were produced.

### 2. Solid State Polymerization

Each PET pellet produced using a Ti-based catalyst or a Sb-based catalyst as described above was introduced into a silo having a length/diameter ratio of 20, and was subjected to preliminary crystallization at 150° C. Subsequently, solid state polymerization was carried out in a nitrogen atmosphere. At this time, the terminal COOH amount (AV) and the IV were regulated as indicated in the following Table 1 by appropriately varying the temperature and time at the time of solid state polymerization.

### 3. Extrusion Molding

The PET pellet that had been subjected to solid state polymerization as described above, and PET recovered waste were used as a PET raw material resin, and this PET raw material resin was dried to a water content of 50 ppm or less. Subsequently, the additives indicated in the following Table 1 were added thereto, and the mixture was mixed with a blender and then was introduced into the hopper of a twin-screw kneading extruder purged with a nitrogen gas stream. As the extruder, a double vent co-rotating intermeshing type twin-screw extruder equipped with screws of the below-described configuration in a barrel having vents installed at two sites, and with a heater (temperature control unit) capable of temperature control, which is partitioned into 9 zones in the longitudinal direction and is installed around the barrel as shown in FIG. 1, was used. A screw having a screw length (L) of 6270 mm and a screw diameter of φ 195 mm was used. Under the extrusion conditions indicated in the following Table 1, while vent evacuation was carried out, extrusion was performed at a speed of screw rotation of 75 rpm and an extrusion output of 3000 kg/hr. Extrusion was carried out by controlling the pressure to the pressure indicated in the following Table 1 using a gear pump, and the product was passed through a filter device (using a filter having the filtration accuracy indicated in the following Table 1). Subsequently, the resultant was closely adhered to a cooling roll using an electrostatic application method.

The gear pump used in the invention included a pair of gears composed of a drive gear and a driven gear provided in a mutually engaged manner, and by driving the drive gear to induce engaged rotation of the two gears, a molten resin was suctioned from the suction port formed in the housing into the cavity. Furthermore, a constant amount of the molten resin was ejected through the ejection port formed on the same housing.

The polyester pellet used had a size of an average major axis of 3 mm to 5 mm, an average minor axis of 1.5 mm to 2.5 mm, and an average length of 4.0 mm to 5.0 mm. Furthermore, the PET recovered waste used was a crushed waste of a polyester film having a size of a thickness of 50 μm to 600 μm and a bulk specific gravity of 0.40 to 0.60 [IV: 0.71 to 0.85, terminal COOH amount: 13 eq/ton to 20 eq/ton].

Vent evacuation was, carried out by bringing a vent suction port close to the casing of the screws of the twin-screw kneading extruder, and by evacuating at the vent suction pressure indicated in the following Table 1.

This twin-screw kneading extruder was equipped with pressure gauges for various parts of the screws on the outer wall of the cylinder, and the pressure gauges were designed such that during the extrusion with rotating screws, the pressure gauges measured the internal pressure of the groove section by scanning along the longitudinal direction of the screw grooves. Since the screws were rotating at the time of extrusion, the pressure gauges apparently scan (measure) the screw groove width direction (minimum distance direction between screw flights). The pressure gauges also have a temperature detecting function, so that the pressure gauges are capable of detecting local heat generation temperature of the resin in the wall area.

<Extrusion Conditions and Regulation Thereof>

(a) Installation Positions of Kneading Disk Unit of Twin-Screw and Vents

As shown in FIG. 1, two kneading disk units were provided, and vacuum vents 16A and 16B were provided in the downstream side of each of the kneading disk units 24A and 24B. The ratio of the length of 24A and the length of 24B was 2:1, and the length sum of 24A and 24B (kneading disk unit length) is indicated in the following Table 1, expressed in the percentage relative to the total screw length. Furthermore, the installation positions of the first kneading disk unit 24A and the second kneading disk unit 24B are indicated in the following Table 1. Each installation position is indicated the distance between the upper stream end of the screw as the starting point and the installation point of each kneading disk unit, and this distance is expressed in percentage relative to the total screw length.

(b) Screw Temperature Pattern

The temperature of the twin-screw extrusion feed port was set at 70° C.; the temperature of the screw in the upstream side of the first kneading disk unit 24A was set at 285° C.; the temperatures of the first and second kneading disk units were set at 275° C.; and the temperature over the region from the back of the second kneading disk unit to the screw outlet was set at 200° C.

(c) Maximum Shear Rate in the Twin-Screw Extruder

The maximum shear rate indicated in the following Table 1 was regulated by varying the speed of rotation of the screw of the twin-screw extruder and the flight clearance of the screw. In addition, the maximum shear rate (y) was determined by the following formula (1).

γ=π·D·N/60h Formula (1)

γ: Maximum shear rate [s^{-1]}

D: Screw diameter [mm]

N: Speed of screw rotation [rpm]

h: Flight clearance [mm]

(d) Extrusion of Melt from Die

The extrusion output of the extruder and the slit height of the die were adjusted. The thickness of the extruded unstretched film was measured by an automatic thickness meter installed at the outlet of the cast drum. The cooling rate of the extruded melt was adjusted to the cooling rate indicated in the following Table 1, by regulating the temperature of the cooling cast drum, and the temperature and air volume of the cold air blown from the auxiliary cooling apparatus installed to face the cooling cast drum. The cooling rate is a cooling rate in the region of from 140° C. to 230° C. of the extruded melt film-like material.

### 4. Stretching

An unstretched film was solidified by extruding on a cooling roll by the method described above, and was subjected to biaxial stretching in order by the following method. Thus, a film having the thickness as indicated in the following Table 1 was obtained.

<Stretching Method>

(a) Longitudinal Stretching

The unstretched film was stretched in the longitudinal direction (transport direction) by passing the film between two nip rolls with different circumferential speeds. Stretching was carried out at a preheating temperature of 95° C., a stretching temperature of 95° C., a stretch ratio of 3.6 times, and a stretching speed of 3000%/second.

(b) Lateral Stretching

The longitudinally stretched film was subjected to lateral stretching using a tenter under the following conditions.

<Conditions>
Preheat temperature: 110° C.
Stretching temperature: 130° C.
Stretch ratio: 4.0 times
Stretching speed: 150%/sec

### 5. Heat Fixing and Thermal Relaxation

Subsequently, the stretched film that completed longitudinal stretching and lateral stretching, was subjected to heat fixing under the following conditions. Furthermore, after the heat fixing, the tenter width was decreased, and thermal relaxation was carried out under the following conditions.

<Heat Fixing Conditions>
Heat fixing temperature: 215° C.
Heat fixing time: 5 seconds

### <Thermal Relaxation Conditions>

(1) Thermal relaxation in the width direction was carried out under the following conditions.
Thermal relaxation temperature: 210° C.
Thermal relaxation ratio: Indicated in the following Table 1.

(2) Thermal relaxation in the longitudinal direction was carried out under the following conditions.

The relaxation treatment in the longitudinal direction of the stretched film was carried out by clamping the two edges in the width direction of the stretched film using the clips installed in a pair of flexurally movable clip chains to which plural chain links were linked in a cyclic form, causing the stretched film to have a bendable structure between the clips, running the clips along guide rails to cause displacement of the bending angle of the chain links, and thereby shortening the distance between clips in the clip run direction.
Thermal relaxation temperature: 210° C.
Thermal relaxation ratio: Indicated in the following Table 1.

### 6. Rolling

After the heat fixing and thermal relaxation, the two edges were trimmed by 10 cm each. Thereafter, the stretched film was subjected to extrusion processing (knurling) along the two edges with a width of 10 mm, and then was rolled at a tension of 80 kg/m. The width was 4.8 m, and the roll length was 2000 m. The thickness unevenness of the formed film was measured with an automatic thickness meter installed before the rolling. The thickness unevenness is indicated in the following Table 2.

### 7. Measurement and Evaluation of PET Pellet and Film

Each of the sample films (PET films) produced as described above was evaluated by measuring the thickness, thickness unevenness, IV, thermal shrinkage, foreign materials, terminal COOH amount (AV), retention ratio of breaking elongation, surface roughness Ra, transport surface state, and voltage resistance. The measurement results are indicated in the following Table 2.

(IV Value)

The IV was determined from the solution viscosity at 30° C. in a mixed solvent of 1,1,2,2-tetrachloroethane/phenol (=⅔ [mass ratio]).

(Terminal COOH Amount (AV))

The PET pellets used as the raw material resin were completely dissolved in a mixed solution of benzyl alcohol/chloroform (=⅔; volume ratio), and the solution was titrated with a standard solution (0.025 N KOH-methanol mixed solution), using phenol red as an indicator. The amount of terminal carboxylic acid groups (eq/ton) was calculated from the titer.

(Thickness Unevenness)

Each sample film was sampled along the entire width at a width of 35 mm (TD sample). A widthwise central portion was sampled with a width of 35 mm and a length of 2 m (MD sample). The TD sample and the MD sample were measured using a continuous film thickness tester (FILM THICKNESS TESTER KG601A, ANRITSU (trade name, made by Anritsu Co., Ltd.) and an average of (maximum value−average value) and (average value−minimum value) was designated as the thickness unevenness variable. Here, the thickness unevenness indicated in Table 2 was determined by the following formula.

Thickness unevenness [%]=Thickness unevenness variable/Average thickness×100%

(Thermal Shrinkage)

With respect to the machine direction (MD; longitudinal direction) and the transverse direction (TD; lateral direction) of each sample film, the sample film on a roll was cut in the MD and TD directions and was humidified at 25° C. and a relative humidity of 60% for 12 hours or longer. Subsequently, the lengths were measured (referred to as MD(F) and TD(F), respectively) using a pin gauge having a length of 20 cm. This film was left to stand in a dry oven at 150° C. for 30 minutes in a tensionless state (thermotreatment). After taking out the film from the oven, the film was humidified at 25° C. and a relative humidity of 60% for 12 hours or longer, and then the lengths were measured (referred to as MD(t) and Td(t), respectively) using a pin gauge having a length of 20 cm. The dimensional changes caused by moisture and heat in the MD and TD directions (δMD(w), δTD(w)) were determined by the following formula, and the values were designated as thermal shrinkage.

δTD(w)(%)=100×|TD(F)−TD(t)|/TD(F)

δMD(w)(%)=100×|MD(F)−MD(t)|/MD(F)

(Foreign Materials)

For a sample film obtained after solid state polymerization, foreign materials in the film were detected using a CCD camera or a base surface state projector (examined by changing the angle using reflected light and transmitted light), and then a magnified image was taken. The presence of any foreign materials was observed using an image processing apparatus, and the number of foreign materials that had a protrusion height of 0.5 μm or greater from the film surface and are present in an area of 100 cm² was determined.

(Retention Time of Breaking Elongation=Hydrolysis Resistance=)

Each sample film was subjected to a thermotreatment at 120° C. and 100% RH for a time period of 10 hours to 300 hours [hr] at an interval of 10 hours, and then the breaking elongation of each sample after the thermotreatment and the breaking elongation of each sample before the thermotreatment were measured. Based on the measured values thus obtained, the breaking elongation after the thermotreatment was divided by the breaking elongation before the thermotreatment, and the retention ratio of breaking elongation for each thermotreatment time was determined by the following formula. The retention ratio of breaking elongation was plotted, on the horizontal axis, against the thermotreatment time on the vertical axis, these data were fitted thereto, and the heat treatment time required until the retention ratio of breaking elongation was 50% (hr; half life of retention ratio of breaking elongation) was determined.

The breaking elongation (%) was determined by cutting a sample specimen having a size of 1 cm×20 cm from a polyester film, and pulling this sample specimen at a distance between chucks of 5 cm and a rate of 20%/minute.

The half-life of retention ratio of breaking elongation is such that as the time is longer, hydrolysis resistance of the polyester film is superior. Maintaining 50% or greater as the retention ratio of breaking elongation is the practically acceptable range for the hydrolysis resistance.

Retention ratio of breaking elongation [%]=(breaking elongation after thermotreatment)/(breaking elongation before thermotreatment)×100

(Surface Roughness Ra)

The surface roughness was measured at 20 sites each in the width direction and the longitudinal direction of the film using a Stylus type roughness tester SE3500K (trade name, manufactured by Kosaka Laboratory, Ltd.) according to JIS B0601, and the average value of the measurements was used.

(Transport Surface State)

While each of the rolled sample films was unwound from an unwinder, the sample film was passed through a heat treatment zone at 180° C. at a transport rate of 50 m/min and was wound at a length of 300 m. The roll shape and the surface (both surfaces) of the film were visually inspected, and thus the transport surface state was evaluated according to the following evaluation criteria.

<Evaluation Criteria>

a: None of creases, scratches, surface unevenness, black zone and roll gap was observed.

b: Creases, scratches, surface unevenness, black zone and roll gap were observed to a small extent, and were recognized at a level acceptable in terms of practical application.

c: Creases, scratches, surface unevenness, black zone and roll gap occurred at multiple sites and were clearly observed by visual inspection, so that the occurrence was recognized at a level unacceptable in terms of practical application.

(Withstand Voltage Characteristics)

Each sample film was subjected to a thermotreatment at 120° C. and 100% RH for 120 hours, and the sample film obtained after the thermotreatment was used to measure the voltage at breakdown (dielectric breakdown voltage) according to the flat plate electrode method in the DC test described in JIS C2151, using ITS-6003 (trade name, manufactured by Tokyo Seiden Co., Ltd.) at a rate of voltage increase of 0.1 kV/sec. The measurement was carried out with n=50, and the average value was designated as the withstand voltage value after thermotreatment. The determined withstand voltage value was divided by the film thickness, and the withstand voltage values per micrometer of the film thickness are shown in Table 2. The measurement was carried out at room temperature of 25° C.

<Production of Back Sheet>

On one surface of each of the sample films obtained as described above, (i) a reflective layer and (ii) a easy adhesive layer as described below were provided by coating in this order.

(i) Reflective Layer (Colored Layer)

First, the various components of the following composition were mixed, and the mixture was subjected to a dispersion treatment for one hour using a Dyno-Mill type disperser. Thus, a pigment dispersion was prepared.

<Formulation of Pigment Dispersion>

| | |
|---|---|
| Titanium dioxide | 39.9 parts |
| (TIPAQUE R-780-2, trade name, manufactured by Ishihara | |
| Sangyo Kaisha, Ltd.; solids content 100%) | |
| Polyvinyl alcohol | 8.0 parts |
| (PVA-105, trade name, manufactured by Kurary Co., Ltd.; | |
| solids content 10%) | |
| Surfactant | 0.5 parts |
| (DEMOL EP,, trade name, manufactured by Kao Corp.; | |
| solids content: 25%) | |
| Distilled water | 51.6 parts |

Subsequently, the pigment dispersion thus obtained was used, and the various components of the following composition were mixed, to thereby prepare a coating liquid for reflective layer formation.

<Formulation of Coating Liquid for Reflective Layer Formation>

| | |
|---|---|
| Pigment dispersion shown above | 80 parts |
| Aqueous dispersion liquid of polyacrylic resin | 19.2 parts |
| (Binder: JURYMER ET410, trade name, manufactured by | |
| Nihon Junyaku Co., Ltd.; solids content: 30% by mass) | |
| Polyoxyalkylene alkyl ether | 3.0 parts |
| (NAROACTY CL95, trade name, manufactured by Sanyo | |
| Chemical Industries, Ltd., solids content: 1% by mass) | |
| Oxazoline compound (crosslinking agent) | 2.0 parts |
| (EPOCROS WS-700, trade name, manufactured by Nippon | |
| Shokubai Co., Ltd.; solids content: 25% by mass) | |
| Distilled water | 7.8 parts |

The coating liquid for reflective layer formation obtained as described above was applied on a sample film using a bar coater, and was dried for one minute at 180° C. Thus, a reflective layer (white layer) having an amount of titanium dioxide application of 6.5 g/m² was formed.

(ii) Easy Adhesive Layer

The various components of the following composition were mixed, and a coating liquid for easy adhesive layer was prepared. This coating liquid was applied on the reflective layer such that the amount of binder application was 0.09 g/m². Thereafter, the coating liquid was dried for one minute at 180° C., and thus an easy adhesive layer was formed.

<Composition of Coating Liquid for Easy Adhesive Layer>

| | |
|---|---|
| Aqueous dispersion liquid of polyolefin resin | 5.2 parts |
| (Binder: CHEMIPEARL S75N, trade name, manufactured | |
| by Mitsui Chemicals, Inc.; solids content: 24% by mass) | |
| Polyoxyalkylene alkyl ether | 7.8 parts |
| (NAROACTY CL95, trade name, manufactured by Sanyo | |
| Chemical Industries, Ltd.; solids content: 1% by mass) | |
| Oxazoline compound | 0.8 parts |
| (EPOCROS WS-700, trade name, manufactured by Nippon | |
| Shokubai Co., Ltd.; solids content: 25% by mass) | |
| Aqueous dispersion of silica fine particles | 2.9 parts |
| (AEROSIL OX-50, trade name, manufactured by Nippon | |
| Aerosil Co., Ltd.; solids content: 10% by mass) | |
| Distilled water | 83.3 parts |

Subsequently, (iii) an undercoat layer, (iv) a barrier layer, and (v) an antifouling layer as described below were provided by coating sequentially from the sample film side, on the surface of the sample film opposite to the side where the reflective layer and the easy adhesive layer were formed.

(iii) Undercoat Layer

The various components of the following composition were mixed, and thus a coating liquid for undercoat layer was prepared. This coating liquid was applied on the sample film and was dried for one minute at 180° C. Thus; an undercoat layer (dried coating amount: about 0.1 g/m²) was formed.

<Composition of Coating Liquid for Undercoat Layer>

| | |
|---|---|
| Polyester resin | 1.7 parts |
| (VYLONAL MD-1200, trade name, manufactured by | |
| Toyobo Co., Ltd.; solids content: 17% by mass) | |
| Polyester resin | 3.8 parts |
| (PESRESIN A-520, trade name, manufactured by | |
| Takamatsu Oil & Fat Co., Ltd.; solids content: | |
| 30% by mass) | |
| Polyoxyalkylene alkyl ether | 1.5 parts |
| (NAROACTY CL95, trade name, manufactured by Sanyo | |
| Chemical Industries, Ltd.; solids content: 1% by mass) | |
| Carbodiimide compound | 1.3 parts |
| (CARBODILITE V-02-L2, trade name, manufactured by | |
| Nisshinbo Chemical Inc.; solids content: 10% by mass) | |
| Distilled water | 91.7 parts |

(iv) Barrier Layer

Subsequently, a vapor deposition film of silicon oxide having a thickness of 800 Å was formed, as a barrier layer, on the surface of the undercoat layer thus formed, under the following vapor deposition conditions.

<Vapor Deposition Conditions>
Reaction gas mixing ratio (unit:slm):Hexamethyldisiloxane/oxygen gas/helium=1/10/10
Degree of vacuum in vacuum chamber: 5.0×10⁻⁶ mbar
Degree of vacuum in vapor deposition chamber: 6.0×10⁻² mbar
Electric power supplied to cooling and electrode drum: 20 kW
Transport speed of film: 80 m/min

(v) Antifouling Layer

As shown below, coating liquids for forming first and second antifouling layers were prepared, and a coating liquid for first antifouling layer and a coating liquid for second antifouling layer were applied in this order on the barrier layer. Thus, an antifouling layer having a two-layer structure was provided.

[First Antifouling Layer]

—Preparation of Coating Liquid for First Antifouling Layer—

The components of the following composition were mixed, and a coating liquid for a first antifouling layer was prepared.

<Composition of Coating Liquid>

| | |
|---|---|
| CERANATE WSA1070 (trade name, manufactured by | 45.9 parts |
| DIC Corp.) | |
| Oxazoline compound (crosslinking agent) | 7.7 parts |
| (EPOCROS WS-700, trade name, manufactured by Nippon | |
| Shokubai Co., Ltd; solids content: 25% by mass) | |
| Polyoxyalkylene alkyl ether | 2.0 parts |
| (NAROACTY CL95, trade name, manufactured by Sanyo | |
| Chemical Industries, Ltd.; solids content: 1% by mass) | |
| Pigment dispersion used in the reflective layer | 33.0 parts |
| Distilled water | 11.4 parts |

—Formation of First Antifouling Layer—

The coating liquid thus obtained was applied on the barrier layer such that the amount of binder application was 3.0 g/m², and was dried for one minute at 180° C. Thus, a first antifouling layer was formed.

[Second antifouling layer]

—Preparation of Coating Liquid for Second Antifouling Layer—

The components of the following composition were mixed, and thus a coating liquid for second antifouling layer was prepared.

<Composition for Coating Liquid>

| | |
|---|---|
| Fluorine-based binder: OBBLIGATO | 45.9 parts |
| (trade name, manufactured by AGC Coat-Tech Co., Ltd.) | |
| Oxazoline compound | 7.7 parts |
| (EPOCROS WS-700, trade name, manufactured by Nippon | |
| Shokubai Co., Ltd; solids content: 25% by mass; | |
| crosslinking agent) | |
| Polyoxyalkylene alkyl ether | 2.0 parts |
| (NAROACTY CL95, trade name, manufactured by Sanyo | |
| Chemical Industries, Ltd.; solids content: 1% by mass) | |
| Pigment dispersion used in the reflective layer | 33.0 parts |
| Distilled water | 11.4 parts |

—Formation of Second Antifouling Layer—

The coating liquid for second antifouling layer thus obtained was applied on the first antifouling layer formed on the barrier layer such that the amount of binder application was 2.0 g/m², and was dried for one minute at 180° C. Thus, a second antifouling layer was formed.

As such, a back sheet having a reflective layer and an easy adhesive layer on one surface of the polyester film and having an undercoat layer, a barrier layer and antifouling layers on the other surface, was produced.

<Production of Solar Cell Module>

Each of the back sheets produced as described above was used and was pasted to a transparent filler (EVA (ethylene-vinyl acetate copolymer; sealant)) so as to obtain the structure shown in FIG. 2 (FIG. 1 of JP-A No. 2009-158952). Thus, a solar cell module of 30 cm squre was produced. At this time, the back sheet was pasted such that the easy adhesive layer of the back sheet was in contact with the transparent filler embedding the solar cell element.

TABLE 1

| | | | | | Polyester film | | | | | | | | | |
|---|---|---|---|---|---|---|---|---|---|---|---|---|---|---|
| | | | | | Twin-screw extrusion conditions | | | | | | | | | |
| | | | | | | | | Kneading | | | | | | |
| | | | | | | | | disk | | | | | Relaxation | |
| | Resin | | | | | | | length | | | | Cooling | conditions | |
| | Raw material resin | | | | | First | Second | (relative | Vent | Gear | | rate for | Relax- | Relax- |
| | Cat- | | AV | | Maximum | kneading | kneading | to total | suction | pump | Filter | ejected | ation | ation |
| | alyst | | [mol/ | Addi- | shear rate | disk % | disk % | screw | pressure | pressure | diameter | ° C./ | ratio in | ratio in |
| | type | IV | ton] | tive | Sec⁻¹ | (*1) | (*1) | length; %) | Torr | Mpa | μm | min | MD % | TD % |
| Example 1 | Ti | 0.73 | 18 | A | 500 | 15 | 60 | 15 | 1 | 15 | 20 | 380 | 3 | 6 |
| Example 2 | | | | | 1500 | | | | | | | | | |
| Example 3 | | | | | 10 | | | | | | | | | |
| Example 4 | | | | | 2000 | | | | | | | | | |
| Comparative | | | | | 2200 | | | | | | | | | |
| Example 1 | | | | | | | | | | | | | | |
| Comparative | | | | | 5 | | | | | | | | | |
| Example 2 | | | | | | | | | | | | | | |
| Example 5 | Ti | 0.71 | 20 | A | 1200 | 10 | 65 | 15 | 1 | 15 | 20 | 340 | 3 | 6 |
| Example 6 | | | | | | 50 | 65 | | | | | | | |
| Example 7 | | | | | | 65 | None | | | | | | | |
| Comparative | | | | | | 75 | None | | | | | | | |
| Example 3 | | | | | | | | | | | | | | |
| Comparative | | | | | | 5 | 70 | | | | | | | |
| Example 4 | | | | | | | | | | | | | | |
| Example 8 | Ti | 0.8 | 15 | A | 1200 | 10 | 55 | 20 | 1 | 15 | 20 | 340 | 3 | 6 |
| Example 9 | | 1 | | | | | | | | | | | | |
| Comparative | | 0.65 | | | | | | | | | | | | |
| Example 5 | | | | | | | | | | | | | | |
| Comparative | | 1.1 | | | | | | | | | | | | |
| Example 6 | | | | | | | | | | | | | | |
| | | | | | Polyester film | | | | | | | | | |
| | | | | | Twin-screw extrusion conditions | | | | | | | | | |
| | | | | | | | | Kneading | | | | Cooling | Relaxation | |
| | Resin | | | | | First | Second | disk | | Gear | | rate for | conditions | |
| | Raw material resin | | | | | kneading | kneading | length | Vent | pump | | ejected | Relax- | Relax- |
| | Cat- | | AV | | Maximum | disk | disk | (relative to | suction | pressure | Filter | melt | ation | ation |
| | alyst | | [mol/ | Addi- | shear rate | position % | position % | total screw | pressure | control | diameter | ° C./ | ratio in | ratio in |
| | type | IV | ton] | tive | Sec⁻¹ | (*1) | (*1) | length; %) | Torr | Mpa | μm | min | MD % | TD % |
| Example 10 | Ti | 0.78 | 15 | B | 400 | 20 | 55 | 10 | 1 | 15 | 20 | 340 | 3 | 6 |
| Example 11 | | | | | 1000 | | | 25 | | | | | | |
| Example 12 | | | | | 50 | | | 1 | | | | | | |
| Example 13 | | | | | 1800 | | | 30 | | | | | | |
| Comparative | | | | | 2100 | | | 35 | | | | | | |
| example 7 | | | | | | | | | | | | | | |
| Comparative | Sb | | 16 | | 2100 | | | 35 | | | | | | |
| Example 8 | | | | | | | | | | | | | | |
| Example 14 | Ti | 0.88 | 12 | D | 1000 | 25 | 55 | 20 | 2 | 20 | 10 | 300 | 3 | 6 |
| Example 15 | | | | | | | | | 10 | | | | | |
| Example 16 | | | | | | | | | 20 | | | | | |
| Example 17 | | | | | | | | | None | | | | | |
| Example 18 | Ti | 0.8 | 14 | C | 800 | 25 | 55 | 5 | 1 | 10 | 5 | 280 | 3 | 6 |
| Example 19 | | | | | | | | | | | 30 | | | |
| Example 20 | | | | | | | | | | | 40 | | | |
| Example 21 | | | | | | | | | | | None | | | |
| Example 22 | Ti | 0.8 | 14 | C | 700 | 25 | 55 | 5 | 2 | 1 | 20 | 250 | 2 | 6 |
| Example 23 | | | | | | | | | | 5 | | | | |
| Example 24 | | | | | | | | | | 30 | | | | |
| Example 25 | | | | | | | | | | None | | | | |
| Example 26 | Ti | 0.85 | 13 | None | 1200 | 25 | 55 | 20 | 0.5 | 10 | 20 | 230 | 5 | 8 |
| Example 27 | | | | | | | | | | | | | 3 | 6 |
| Example 28 | | | | | | | | | | | | | 1 | 3 |
| Example 29 | | | | | | | | | | | | | 0 | 0 |

*1: Position determined based on the upstream end as starting point
Additive types (“mass %” refers to the ratio with respect to the raw material resin):
A: Silica inorganic fine particles 0.1 mass %
B: UV absorber 1.8 mass % + Silica fine particles 0.1 mass % (UV absorber: 2-[3-(3,3,5-trimethylhexyloxy)benzoyl]-4,6-bis-(2-hydroxyphenyl)-1,3,5-triazine)
C: TiO₂ fine particles 5 mass %
D: Recovered chip waste 5 mass % + Silica fine particles 0.2 mass %

TABLE 2

| | Polyester film | | | | | | | | | |
|---|---|---|---|---|---|---|---|---|---|---|
| | Evaluation | | | | | | | | | |
| | | | | | | | Half | | | |
| | | | | | | | retention | | | Withstand voltage |
| | | | | | | | time of | | | characteristics |
| | | | | Thermal | Thermal | Foreign | breaking | Surface | Transport | after |
| | Thickness | Thickness | | shrinkage | shrinkage | materials | elongation | roughness Ra | surface | thermotreatment |
| | μm | unevenness % | IV | in MD % | in TD % | pieces/100 cm² | hr | nm | state | V/μm |
| Example 1 | 270 | 0.1 | 0.72 | 0.3 | 0.4 | 20 | 93 | 100 | a | 135 |
| Example 2 | | 0.2 | 0.69 | 0.3 | 0.5 | 15 | 95 | 150 | a | 125 |
| Example 3 | | 2 | 0.73 | 0.6 | 0.7 | 90 | 90 | 180 | b | 109 |
| Example 4 | | 4 | 0.65 | 0.8 | 1 | 100 | 80 | 200 | b | 90 |
| Comparative | | 6 | 0.6 | 1.3 | 1.7 | 165 | 50 | 280 | c | 35 |
| Example 1 | | | | | | | | | | |
| Comparative | | 5 | 0.7 | 1 | 1.2 | 800 | 62 | 600 | c | 40 |
| Example 2 | | | | | | | | | | |
| Example 5 | 250 | 0.5 | 0.7 | 0.2 | 0.4 | 25 | 85 | 80 | a | 123 |
| Example 6 | | 0.6 | 0.78 | 0.5 | 0.7 | 50 | 80 | 135 | a | 117 |
| Example 7 | | 2 | 0.95 | 0.7 | 1 | 100 | 70 | 169 | b | 98 |
| Comparative | | 5 | 0.63 | 1.9 | 3.2 | 250 | 60 | 300 | c | 45 |
| Example 3 | | | | | | | | | | |
| Comparative | | 7 | 0.65 | 0.04 | 3 | 600 | 50 | 450 | c | 50 |
| Example 4 | | | | | | | | | | |
| Example 8 | 250 | 1 | 0.77 | 0.7 | 0.9 | 23 | 105 | 50 | a | 130 |
| Example 9 | | 0.5 | 0.95 | 0.9 | 1 | 100 | 125 | 115 | a | 125 |
| Comparative | | 6 | 0.6 | 0.3 | 0.6 | 90 | 55 | 170 | c | 48 |
| Example 5 | | | | | | | | | | |
| Comparative | | Due to high viscosity, ejection failure, rupture during elongation, evaluation not possible | | | | | | | | |
| Example 6 | | | | | | | | | | |
| Example 10 | 250 | 0.2 | 0.78 | 0.5 | 0.6 | 10 | 105 | 50 | a | 140 |
| Example 11 | | 0.3 | 0.75 | 0.4 | 0.5 | 60 | 95 | 115 | a | 120 |
| Example 12 | | 3 | 0.79 | 0.7 | 0.8 | 95 | 100 | 186 | b | 115 |
| Example 13 | | 5 | 0.7 | 0.9 | 1 | 100 | 75 | 170 | b | 110 |
| Comparative | | 7 | 0.6 | 1 | 1.5 | 320 | 55 | 370 | c | 47 |
| example 7 | | | | | | | | | | |
| Comparative | | 10 | 0.5 | 1.2 | 1.8 | 530 | 35 | 475 | c | 28 |
| Example 8 | | | | | | | | | | |
| Example 14 | 188 | 0.7 | 0.86 | 0.6 | 0.9 | 9 | 120 | 90 | a | 165 |
| Example 15 | | 0.6 | 0.85 | 0.5 | 0.8 | 16 | 115 | 120 | a | 155 |
| Example 16 | | 2.7 | 0.82 | 0.5 | 0.7 | 35 | 110 | 150 | b | 130 |
| Example 17 | | 3.1 | 0.78 | 0.9 | 1 | 48 | 95 | 180 | b | 115 |
| Example 18 | 150 | 1 | 0.77 | 0.3 | 0.4 | 5 | 95 | 60 | a | 160 |
| Example 19 | | 2.4 | 0.78 | 0.4 | 0.5 | 60 | 95 | 205 | a | 155 |
| Example 20 | | 3 | 0.79 | 0.5 | 0.8 | 85 | 90 | 250 | a | 153 |
| Example 21 | | 3.1 | 0.79 | 0.7 | 0.9 | 100 | 90 | 380 | b | 129 |
| Example 22 | 125 | 3 | 0.74 | 0.2 | 0.4 | 50 | 85 | 90 | b | 155 |
| Example 23 | | 1.1 | 0.77 | 0.1 | 0.3 | 20 | 90 | 50 | a | 150 |
| Example 24 | | 0.5 | 0.73 | 0.05 | 0.2 | 80 | 90 | 60 | a | 145 |
| Example 25 | | 5 | 0.72 | 0.08 | 0.3 | 100 | 70 | 130 | b | 130 |
| Example 26 | 75 | 0.3 | 0.8 | 0.03 | 0.06 | 22 | 105 | 60 | a | 150 |
| Example 27 | | 0.5 | 0.8 | 0.08 | 0.12 | 23 | 100 | 75 | a | 145 |
| Example 28 | | 1.4 | 0.8 | 0.15 | 0.28 | 25 | 100 | 90 | a | 140 |
| Example 29 | | 2.3 | 0.79 | 0.85 | 1 | 25 | 100 | 110 | b | 132 |

As shown in Tables 1 and 2, in the Examples, the time taken to reach the half-retention time of breaking elongation was longer, high hydrolysis resistance was exhibited, and the voltage resistance exhibited satisfactory values. From this, the polyester film of the invention can exhibit high durability performance for a long time period, for example, even in the high temperature and high humidity environments such as outdoors, or in applications in which the polyester film is left to stand under light exposure for a long time.

On the other hand, in the Comparative Examples, the breaking elongation was prone to be largely decreased, was significantly deteriorated in terms of hydrolysis resistance, and could not maintain satisfactory voltage resistance.

The polyester film of the invention is suitably used in the applications of, for example, a rear surface sheet that constitutes a solar cell module (sheet that is disposed on the opposite side of the incident side of sunlight in a solar cell element; so-called back sheet).

The invention includes the following exemplary embodiments.

<1> A method for producing a polyester film, the method comprising: subjecting a polyester raw material resin, which contains a titanium compound as a polymerization catalyst and has an intrinsic viscosity of from 0.71 to 1.00, to melt extrusion using a twin-screw extruder which includes a cylinder; two screws disposed inside the cylinder; and a kneading disk unit disposed in at least a portion of a region extending from a 10%-position to a 65%-position of screw length with respect to an upstream end of the screws in a resin extrusion direction as a starting point, at a maximum shear rate (γ) generated inside the twin-screw extruder of from 10 sec⁻¹ to 2000 sec⁻¹; forming an unstretched film by cooling and solidifying the melt extruded polyester resin on a cast roll; subjecting the unstretched film to biaxial stretching in a longitudinal direction and a lateral direction; and heat fixing the stretched film formed by biaxial stretching.
<2> The method for producing a polyester film according to <1>, wherein the melt extrusion comprises using a kneading disk unit having a length of from 1% to 30% in a longitudinal direction of the screw.
<3> The method for producing a polyester film according to <1> or <2>, wherein the melt extrusion further comprises performing suction through vents provided on the cylinder of the twin-screw extruder.
<4> The method for producing a polyester film according to any one of <1> to <3>, wherein the twin-screw extruder comprises, in a downstream of the cylinder in the resin extrusion direction, a gear pump for extrusion control which controls an extrusion output of the resin and a filter for foreign material removal which removes foreign materials from the resin.
<5> The method for producing a polyester film according to any one of <1> to <4>, wherein forming of the unstretched film comprises cooling and solidification in a region in which a temperature of the polyester resin that is melt extruded from the twin-screw extruder is from 140° C. to 230° C., at an average cooling rate in a range of from 230° C./min to 500° C./min.
<6> The method for producing a polyester film according to any one of <1> to <5>, further comprising, after the heat fixing, subjecting the heat fixed stretched film to a relaxation treatment in the longitudinal direction and the lateral direction of the film.
<7> The method for producing a polyester film according to <6>, wherein the relaxation treatment is performed in the longitudinal direction of the stretched film by clamping two edges in the width direction of the stretched film using clips installed in a pair of flexurally movable clip chains to which plural chain links are linked in a cyclic form, causing the stretched film to have a bendable structure between the clips, running the clips along guide rails to cause displacement of the bending angle of the chain links, and thereby shortening the distance between clips in the clip run direction.
<8> The method for producing a polyester film according to any one of <1> to <7>, wherein an amount of terminal carboxylic acid groups in the polyester raw material resin is from 8 eq/ton to 25 eq/ton.
<9> The method for producing a polyester film according to any one of <1> to <8>, wherein the polyester raw material resin contains recovered waste of a polyester resin in an amount of from 0% by mass to 15% by mass relative to a total mass of the polyester raw material resin.
<10> The method for producing a polyester film according to any one of <1> to <9>, wherein the titanium compound is an organic chelate titanium complex.
<11> A polyester film produced by the method for producing a polyester film according to any one of <1> to <10>.
<12> The polyester film according to <11>, which comprises titanium atoms derived from a polymerization catalyst and has an intrinsic viscosity of from 0.71 to 1.00, and wherein time taken for breaking elongation obtainable after a heat-moisture treatment in an atmosphere at a temperature of 120° C. and a relative humidity of 100%, to reach 50% relative to the breaking elongation prior to the heat-moisture treatment, is from 65 hours to 150 hours.
<13> The polyester film according to <11> or <12>, wherein the amount of foreign materials having a protrusion height from the film surface of 0.5 μm or more is from 1 to 100 pieces/100 cm², and the surface roughness Ra is from 20 nm to 200 nm.
<14> A back sheet for a solar cell, comprising the polyester film according to any one of <11> to <13>.
<15> A solar cell module comprising the polyester film according to any one of <11> to <14>.

All publications, patent applications, and technical standards mentioned in this specification are herein incorporated by reference to the same extent as if each individual publication, patent application, or technical standard was specifically and individually indicated to be incorporated by reference.

What is claimed is:

1. A method for producing a polyester film, the method comprising:
subjecting a polyester raw material resin, which contains a titanium compound as a polymerization catalyst and has an intrinsic viscosity of from 0.71 to 1.00, to melt extrusion using a twin-screw extruder which includes a cylinder; two screws disposed inside the cylinder; and a kneading disk unit disposed in at least a portion of a region extending from a 10%-position to a 65%-position of screw length with respect to an upstream end of the screws in a resin extrusion direction as a starting point, at a maximum shear rate (γ) generated inside the twin-screw extruder of from 10 sec⁻¹ to 2000 sec⁻¹;
forming an unstretched film by cooling and solidifying the melt extruded polyester resin on a cast roll;
subjecting the unstretched film to biaxial stretching in a longitudinal direction and a lateral direction; and
heat fixing the stretched film formed by biaxial stretching.

2. The method for producing a polyester film according to claim 1, wherein the melt extrusion comprises using a kneading disk unit having a length of from 1% to 30% in a longitudinal direction of the screw.

3. The method for producing a polyester film according to claim 1, wherein the melt extrusion further comprises performing suction through vents provided on the cylinder of the twin-screw extruder.

4. The method for producing a polyester film according to claim 1, wherein the twin-screw extruder comprises, in a downstream of the cylinder in the resin extrusion direction, a gear pump for extrusion control which controls an extrusion output of the resin and a filter for foreign material removal which removes foreign materials from the resin.

5. The method for producing a polyester film according to claim 1, wherein forming of the unstretched film comprises cooling and solidification in a region in which a temperature of the polyester resin that is melt extruded from the twin-screw extruder is from 140° C. to 230° C., at an average cooling rate in a range of from 230° C./min to 500° C./min.

6. The method for producing a polyester film according to claim 1, further comprising, after the heat fixing, subjecting the heat fixed stretched film to a relaxation treatment in the longitudinal direction and the lateral direction of the film.

7. The method for producing a polyester film according to claim 6, wherein the relaxation treatment is performed in the longitudinal direction of the stretched film by clamping two edges in the width direction of the stretched film using clips installed in a pair of flexurally movable clip chains to which plural chain links are linked in a cyclic form, causing the stretched film to have a bendable structure between the clips, running the clips along guide rails to cause displacement of the bending angle of the chain links, and thereby shortening the distance between clips in the clip run direction.

8. The method for producing a polyester film according to claim 1, wherein an amount of terminal carboxylic acid groups in the polyester raw material resin is from 8 eq/ton to 25 eq/ton.

9. The method for producing a polyester film according to claim 1, wherein the polyester raw material resin contains recovered waste of a polyester resin in an amount of from 0% by mass to 15% by mass relative to a total mass of the polyester raw material resin.

10. The method for producing a polyester film according to claim 1, wherein the titanium compound is an organic chelate titanium complex.

11. A polyester film produced by the method for producing a polyester film according to claim 1.

12. The polyester film according to claim 11, which comprises titanium atoms derived from a polymerization catalyst and has an intrinsic viscosity of from 0.71 to 1.00, and wherein time taken for breaking elongation obtainable after a heat-moisture treatment in an atmosphere at a temperature of 120° C. and a relative humidity of 100%, to reach 50% relative to the breaking elongation prior to the heat-moisture treatment, is from 65 hours to 150 hours.

13. The polyester film according to claim 11, wherein the amount of foreign materials having a protrusion height from the film surface of 0.5 μm or more is from 1 to 100 pieces/100 cm², and the surface roughness Ra is from 20 nm to 200 nm.

14. A back sheet for a solar cell, comprising the polyester film according to claim 11.

15. A solar cell module comprising the polyester film according to claim 11.
